(19) United States
(12) Patent Application Publication
(10) Pub. No.: US 2026/0199826 A1
(43) Pub. Date: Jul. 16, 2026

(54) EXHAUST GAS PRETREATMENT EQUIPMENT FOR SEMICONDUCTOR MANUFACTURING FACILITIES

(71) Applicant: LOT CES CO., LTD., Osan-si, Gyeonggi-do (KR)

(72) Inventors: Ho Sik KIM, Osan-si, Gyeonggi-do (KR); Soo Jung PARK, Hwaseong-si, Gyeonggi-do (KR); Jin Ho BAE, Hwaseong-si Gyeonggi-do (KR); Jong Taek LEE, Hwaseong-si, Gyeonggi-do (KR); Ji Young KIM, Osan-si, Gyeonggi-do (KR); Do Won KIM, Pyeongtaek-si, Gyeonggi-do (KR); Tae Hyung LEE, Hwaseong-si, Gyeonggi-do (KR); Yon Woo CHOI, Namyangju-si, Gyeonggi-do (KR); Hyung Jun KIM, Osan-si, Gyeonggi-do (KR)

(73) Assignee: LOT CES CO., LTD., Osan-si, Gyeonggi-do (KR)

(21) Appl. No.: 18/714,171

(22) PCT Filed: Nov. 30, 2023
(86) PCT No.: PCT/KR2023/019563

§ 371 Date: May 29, 2024

(30) Foreign Application Priority Data
Dec. 14, 2022 (KR) 10-2022-0174552
Sep. 6, 2023 (KR) 10-2023-0118532

(51) Int. Cl. B01D 53/32; B01D 53/72; H10P 72/00

(52) U.S. Cl. CPC B01D 53/32; B01D 53/72; H10P 72/0402; B01D 2257/556; B01D 2257/706; B01D 2258/0216; B01D 2259/818

(57) ABSTRACT

Provided is exhaust gas pretreatment equipment for semiconductor manufacturing facilities, the exhaust gas pretreatment equipment for pretreating an exhaust gas discharged from a semiconductor process chamber in which a semiconductor manufacturing process using a process gas is performed, by using a vacuum pump through a chamber exhaust pipe connecting the semiconductor process chamber to the vacuum pump, the exhaust gas pretreatment equipment including an exhaust pipe plasma reactor installed on the chamber exhaust pipe and generating plasma in the exhaust gas to remove ingredients to be removed contained in the exhaust gas, and a remote plasma reactor generating plasma to decompose a remote plasma source gas and generating a remote plasma gas including reactive species, wherein the remote plasma gas is supplied to a section between the exhaust pipe plasma reactor and the vacuum pump in a flow line of the exhaust gas.

### TECHNICAL FIELD

The present invention relates to semiconductor manufacturing equipment technology, and more particularly, to technology for converting powder contained in gas discharged from a process chamber of a semiconductor manufacturing facility into a gas phase and discharging gas.

### BACKGROUND ART

Semiconductor devices have been manufactured by repeatedly performing processes such as photolithography, etching, diffusion and metal deposition, and the like on a wafer in a semiconductor process chamber by using various process gases. After the processes are completed in the semiconductor process chamber, a residual gas is present in the semiconductor process chamber, and since the residual gas in the process chamber contains toxic ingredients, the residual gas is discharged by a vacuum pump and is purified by exhaust gas treatment equipment such as a scrubber. However, in the process of exhaust gas flowing, powder is deposited on the vacuum pump and an exhaust pipe connecting the vacuum pump to the scrubber, which reduces the fluidity of an exhaust gas and shortens a mean time between failure (MTBF) of the equipment.

Korean Patent Laid-open Publication No. 10-2007-0024806 discloses technology for preventing solidification due to a decrease in the temperature of exhaust gas by installing a heating jacket on a vacuum pipe.

### DETAILED DESCRIPTION OF THE INVENTION

### Technical Problem

The present invention provides exhaust gas pretreatment equipment for pretreating exhaust gas so as to prevent the fluidity of the exhaust gas discharged from a process chamber in which a semiconductor manufacturing process using various process gases is performed in a semiconductor manufacturing facility from being reduced.

### Technical Solution

According to an aspect of the present invention, there is provided exhaust gas pretreatment equipment for semiconductor manufacturing facilities, the exhaust gas pretreatment equipment for pretreating an exhaust gas discharged from a semiconductor process chamber in which a semiconductor manufacturing process using a process gas is performed, by using a vacuum pump through a chamber exhaust pipe connecting the semiconductor process chamber to the vacuum pump, the exhaust gas pretreatment equipment including an exhaust pipe plasma reactor installed on the chamber exhaust pipe and generating plasma in the exhaust gas to remove ingredients to be removed contained in the exhaust gas, and a remote plasma reactor generating plasma to decompose a remote plasma source gas and generating a remote plasma gas including reactive species, wherein the remote plasma gas is supplied to a section between the exhaust pipe plasma reactor and the vacuum pump in a flow line of the exhaust gas.

According to another aspect of the present invention, there is provided exhaust gas pretreatment equipment for semiconductor manufacturing facilities, the exhaust gas pretreatment equipment for pretreating an exhaust gas discharged from a semiconductor process chamber in which a semiconductor manufacturing process using a process gas is performed, by using a vacuum pump through a chamber exhaust pipe connecting the semiconductor process chamber to the vacuum pump, the exhaust gas pretreatment equipment including an exhaust pipe plasma reactor installed on the chamber exhaust pipe and generating plasma in the exhaust gas to remove ingredients to be removed contained in the exhaust gas, and a remote plasma reactor generating plasma to decompose a remote plasma source gas and generating a remote plasma gas including reactive species, wherein the remote plasma gas is supplied to a section between the semiconductor process chamber and the exhaust pipe plasma reactor in a flow line of the exhaust gas.

### Effects of the Invention

According to the present invention, all of the objectives of the present invention described above can be achieved. Specifically, powder stabilized in an exhaust gas is generated by an exhaust gas plasma reactor installed at an exhaust pipe, reactive species generated in a remote plasma reactor are supplied to a section between the exhaust pipe plasma reactor and a vacuum pump in a flow line of the exhaust gas or is supplied to the upstream of the exhaust pipe plasma reactor and reacts with the stabilized powder so that the powder is gasified and the power is prevented from being stacked in exhaust equipment and thus reduction of fluidity of the exhaust gas can be effectively prevented.

### BRIEF DESCRIPTION OF THE DRAWINGS

FIG. 1 is a diagram illustrating a schematic configuration of a semiconductor manufacturing facility in which exhaust gas pretreatment equipment according to a first embodiment of the present invention is installed;

FIG. 2 is a longitudinal cross-sectional view of an exhaust pipe plasma reactor provided in the semiconductor manufacturing facility shown in FIG. 1;

FIG. 3 is a perspective view of a magnetic core provided in the exhaust pipe plasma reactor shown in FIG. 2;

FIG. 4 is a longitudinal cross-sectional view of a remote plasma reactor provided in the semiconductor manufacturing facility shown in FIG. 1;

FIG. 5 is a perspective view of a magnetic core provided in the remote plasma reactor shown in FIG. 4;

FIG. 6 is a diagram illustrating a schematic configuration of a semiconductor manufacturing facility in which exhaust gas pretreatment equipment according to a second embodiment of the present invention is installed;

FIG. 7 is a diagram illustrating a schematic configuration of a semiconductor manufacturing facility in which exhaust gas pretreatment equipment according to a third embodiment of the present invention is installed;

FIG. 8 is a diagram illustrating a schematic configuration of a semiconductor manufacturing facility in which exhaust gas pretreatment equipment according to a fourth embodiment of the present invention is installed;

FIG. 9 is a diagram illustrating a schematic configuration of a semiconductor manufacturing facility in which exhaust gas pretreatment equipment according to a fifth embodiment of the present invention is installed;

FIG. 10 is a diagram illustrating a schematic configuration of a semiconductor manufacturing facility in which exhaust gas pretreatment equipment according to a sixth embodiment of the present invention is installed;

FIG. 11 is a diagram illustrating a schematic configuration of a semiconductor manufacturing facility in which exhaust gas pretreatment equipment according to a seventh embodiment of the present invention is installed;

FIG. 12 is a diagram illustrating a schematic configuration of a semiconductor manufacturing facility in which exhaust gas pretreatment equipment according to an eighth embodiment of the present invention is installed;

FIG. 13 is a diagram illustrating a schematic configuration of a semiconductor manufacturing facility in which exhaust gas pretreatment equipment according to a ninth embodiment of the present invention is installed; and

FIG. 14 is a diagram illustrating a schematic configuration of a semiconductor manufacturing facility in which exhaust gas pretreatment equipment according to a tenth embodiment of the present invention is installed.

### MODE FOR CARRYING OUT THE INVENTION

Hereinafter, the configuration and operation of the present invention will be described in detail with reference to the accompanying drawings.

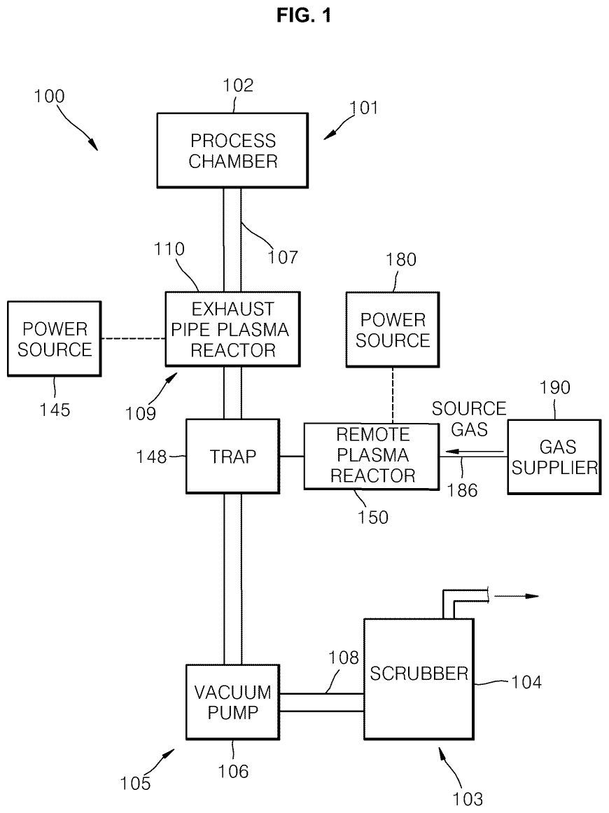

FIG. 1 is a block diagram illustrating a schematic configuration of a semiconductor manufacturing facility in which exhaust gas pretreatment equipment according to a first embodiment of the present invention is installed. Referring to FIG. 1, a semiconductor manufacturing facility 100 includes semiconductor manufacturing equipment 101 in which a semiconductor manufacturing process for manufacturing a semiconductor device is performed, gas purification equipment 103 for purifying gas discharged from the semiconductor manufacturing equipment 101, exhaust equipment 105 for discharging gas from the semiconductor manufacturing equipment 101 to allow the gas to flow into the gas purification equipment 103, and exhaust gas pretreatment equipment 109 according to the first embodiment of the present invention that prevents reduction of the fluidity of the gas by pretreating gas discharged from the semiconductor manufacturing equipment 101.

The semiconductor manufacturing equipment manufactures a semiconductor device by performing a semiconductor manufacturing process. The semiconductor manufacturing equipment 101 includes a semiconductor process chamber 102 in which the semiconductor manufacturing process using various process gases is performed. Although not shown, the semiconductor manufacturing equipment 101 further includes a process gas supply unit for supplying process various types of gases required for the semiconductor process chamber 102.

The semiconductor process chamber 102 includes all types of semiconductor process chambers that are generally used to manufacture the semiconductor device in a technical field of a semiconductor manufacturing facility. A residual gas generated in the semiconductor process chamber 102 is discharged by the exhaust equipment 105 to the outside and is purified by the gas purification equipment 103.

In the present embodiment, a semiconductor process to be performed in the semiconductor process chamber 102 may be a SiO₂ process of forming a silicon oxide layer on a substrate, a TiO₂ process of forming a titanium dioxide layer on the substrate, a ZrO₂ process of forming a zirconia layer on the substrate, an HfO₂ process of forming an oxide hafnium layer on the substrate, a Nb₂O₅ process of forming a niobium pentoxide layer on the substrate, a Ta₂O₅ of forming a tantalum pentoxide layer on the substrate, and an amorphous carbon layer (ACL) process of forming an ACL on the substrate.

In the SiO₂ process, a silicon dioxide (SiO₂) layer is formed. In the present embodiment, it will be described that a process gas including Si(OC₂H₅)₄ tetraethyl orthosilicate (TEOS) is used as a precursor to generate silicon dioxide (SiO₂) in the SiO₂ process. After the SiO₂ process is performed, an exhaust gas including unresponsive TEOS is discharged from the semiconductor process chamber 102 by the exhaust equipment 105. TEOS contained in the exhaust gas of the SiO₂ process reacts with oxygen so that silicon dioxide (SiO₂) powder may be generated as a by-product, and the SiO₂ powder accumulates in the exhaust gas 105 and reduces the fluidity of the exhaust gas.

In the TiO₂ process, a titanium dioxide (TiO₂) layer is formed on the substrate. In the present invention, it will be described that a process gas including titanium tetraethoxide Ti(OCH₂CH₃)₄ is used as a precursor to generate TiO₂ in the TiO₂ process. After the TiO₂ process is performed, an exhaust gas including unresponsive Ti(OCH₂CH₃)₄ is discharged from the semiconductor process chamber 102 by the exhaust equipment 105. Ti(OCH₂CH₃)₄ contained in the exhaust gas of the TiO₂ process reacts with oxygen so that titanium dioxide (TiO₂) powder may be generated as a by-product, and the TiO₂ powder accumulates in the exhaust equipment 105 and reduces the fluidity of the exhaust gas.

In the ZrO₂ process, a zirconia dioxide (ZrO₂) layer is formed on the substrate. In the present embodiment, it will be described that a process gas including (C₅H₅)Zr(N(CH₃)₂)₃ is used as a precursor to generate ZrO₂ in the ZrO₂ process. After the ZrO₂ process is performed, an exhaust gas including unresponsive (C₅H₅)Zr(N(CH₃)₂)₃ is discharged from the semiconductor process chamber 102 by the exhaust equipment 105. (C₅H₅)Zr(N(CH₃)₂)₃ contained in the exhaust gas of the ZrO₂ process reacts with oxygen so that zirconia dioxide (ZrO₂) powder may be generated as a by-product, and the ZrO₂ powder accumulates in the exhaust powder 105 and reduces the fluidity of the exhaust gas.

In the HfO₂ process, a hafnium dioxide (HfO₂) layer is formed on the substrate. In the present embodiment, it will be described that a process gas including (C₅H₅)Hf(N(CH₃)₂)₃ is used as a precursor to generate HfO₂ in the HfO₂ process. After the HfO₂ process is performed, a process gas including unresponsive (C₅H₅)Hf(N(CH₃)₂)₃ is discharged from the semiconductor process chamber 102 by the exhaust equipment 105. (C₅H₅)Hf(N(CH₃)₂)₃ contained in the exhaust gas of the HfO₂ process reacts with oxygen so that hafnium dioxide (HfO₂) power may be generated, and the HfO₂ powder accumulates in the exhaust equipment 105 and reduces the fluidity of the exhaust gas.

In the Nb₂O₅ process, a niobium pentoxide (Nb₂O₅) layer is formed on the substrate. In the present embodiment, it will be described that a process gas including (C₅H₅)Nb(N(CH₃)₂)₃ is used as a precursor to generate Nb₂O₅ in the Nb₂O₅ process. After the Nb₂05 process is performed, an exhaust gas including unresponsive (C₅H₅)Nb(N(CH₃)₂)₃ is discharged from the semiconductor process chamber 102 by the exhaust equipment 105. (C₅H₅)Nb(N(CH₃)₂)₃ contained in the exhaust gas of the Nb₂05 process reacts with oxygen so that Nb₂O₅ powder may be generated as a by-product, and the Nb₂O₅ powder accumulates in the exhaust equipment 105 and reduces the fluidity of the exhaust gas.

In the Ta₂O₅ process, a tantalum pentoxide (Ta₂O₅) layer is formed on the substrate. In the present embodiment, it will be described that a process gas including Ta(OC₂H₅)₅ is used as a precursor to generate Ta₂O₅ in the Ta₂O₅ process. After the Ta₂O₅ process is performed, an exhaust gas including unresponsive Ta(OC₂H₅)₅ is discharged from the semiconductor process chamber 102 by the exhaust equipment 105. Ta(OC₂H₅)₅ contained in the exhaust gas of the Ta₂O₅ process reacts with oxygen so that tantalum pentoxide (Ta₂O₅) powder may be generated, and the Ta₂O₅ powder accumulates in the exhaust equipment 105 and reduces the fluidity of the exhaust gas.

In the ACL process, an ACL is formed on the substrate. The ACL process is performed when amorphous carbon is deposited on the substrate in the semiconductor process chamber 102. After the ACL process is performed, a residual gas including hydrogenated amorphous carbon (a-C:H) is generated in the semiconductor process chamber 102. After the ACL process is performed, an exhaust gas including hydrogenated amorphous carbon (a-C:H) is discharged from the semiconductor process chamber 102 by the exhaust equipment 105. Hydrogenated amorphous carbon (a-C: H) contained in the exhaust gas of the ACL process accumulates in the exhaust equipment 105 and reduces the fluidity of the exhaust gas.

The gas purification equipment 103 treats harmful ingredients contained in the exhaust gas discharged from the semiconductor process chamber 102 by the exhaust equipment 106. The gas purification equipment 103 includes a scrubber 104 for treating the exhaust gas. The scrubber 104 includes all types of scrubbers generally used to purify the exhaust gas in the technical field of a semiconductor manufacturing facility.

The exhaust equipment 105 discharges the residual gas generated in the semiconductor process chamber 102 after the process from the semiconductor process chamber 102. The exhaust equipment 105 includes a vacuum pump 106, a chamber exhaust pipe 107 connecting the semiconductor process chamber 102 to the vacuum pump 106, and a pump exhaust pipe 108 extending from the vacuum pump 106 downstream.

The vacuum pump 106 forms a negative pressure in the semiconductor process chamber 102 through the chamber exhaust pipe 107 that connects the semiconductor process chamber 102 to the vacuum pump 106, so as to discharge the residual gas in the semiconductor process chamber 102 from the semiconductor process chamber 102. The vacuum pump 106 includes the configuration of a vacuum pump that is generally used to discharge gas in the technical field of the semiconductor manufacturing facility and thus, here, detailed descriptions thereof will be omitted. Powder accumulates in the vacuum pump 106 so that the performance of the vacuum pump 106 may be reduced. According to the exhaust gas pretreatment equipment 109 of the present invention, accumulation of powder in the vacuum pump 106 is suppressed so that a mean time between failure (MTBF) of the vacuum pump 106 is extended.

The chamber exhaust pipe 107 connects an exhaust of the semiconductor process chamber 102 to an intake of the vacuum pump 106 between the semiconductor process chamber 102 and the vacuum pump 106. The residual gas in the semiconductor process chamber 102 is discharged as an exhaust gas through the chamber exhaust pipe 107 by the negative pressure generated by the vacuum pump 106. While the exhaust gas flows through the chamber exhaust pipe 107, the exhaust gas is pretreated by the exhaust gas pretreatment equipment 109.

The pump exhaust pipe 108 extends from the vacuum pump 106 downstream. The pump exhaust pipe 108 is connected to an outlet of the vacuum pump 106 so that the exhaust gas discharged from the vacuum pump 106 flows into the pump exhaust pipe 108. The scrubber 104 is connected to a downstream end of the pump exhaust pipe 108 so that the exhaust gas discharged from the vacuum pump 106 flows into the scrubber 104 through the pump exhaust pipe 108.

The exhaust gas pretreatment equipment 109 pretreats the exhaust gas discharged from the semiconductor process chamber 102 so as to prevent reduction of the fluidity of the exhaust gas discharged from the semiconductor process chamber 102. The exhaust gas pretreatment equipment 109 includes an exhaust pipe plasma reactor 110 that generates a plasma reaction with respect to the exhaust gas discharged from the semiconductor process chamber 102, an exhaust pipe reactor power source 145 that supplies power to the exhaust pipe plasma reactor 110, a powder collection trap 148 installed on the chamber exhaust pipe 107 to collect powder, a remote plasma reactor 150 that generates reactive species to be supplied to the powder collection trap 148 by using plasma, a remote reactor power source 180 that supplies power to the remote plasma reactor 150, and a remote plasma source gas supplier 190 that supplies gas to the remote plasma reactor 150.

The exhaust pipe plasma reactor 110 is installed on the chamber exhaust pipe 107 and generates a plasma reaction with respect to the exhaust gas discharged from the semiconductor process chamber 102. The exhaust pipe plasma reactor 110 performs a function of primarily removing ingredients to be removed contained in the exhaust gas discharged from the semiconductor process chamber 102. In the present embodiment, it will be described that the exhaust pipe plasma reactor 110 is an inductively coupled plasma (ICP) reactor using ICP. Although, in the present embodiment, it has been described that the exhaust pipe plasma reactor 110 uses ICP, the present invention is not limited thereto. In the present invention, the exhaust pipe plasma reactor includes all types of plasma reactors (e.g., a plasma reactor using capacitively coupled plasma (CCP)) that generates a plasma reaction, and this also belongs to the scope of the present invention.

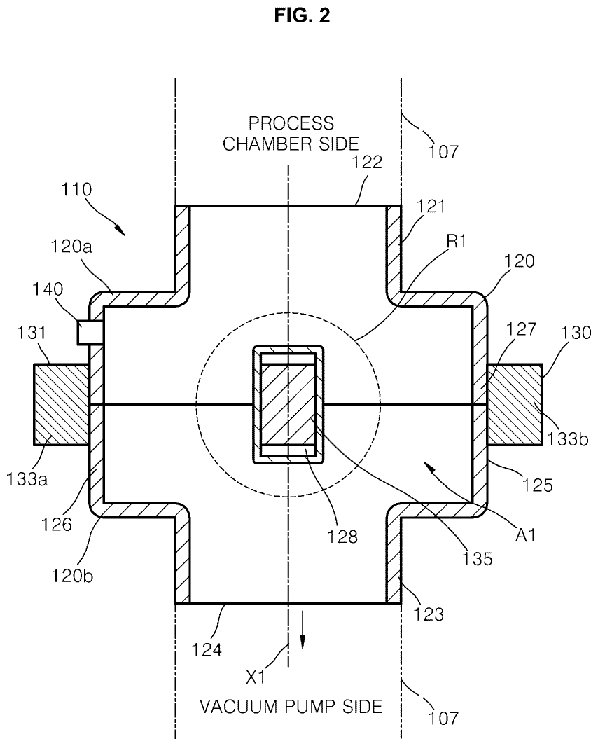

FIG. 2 is a longitudinal cross-sectional view of the exhaust pipe plasma reactor 110. Referring to FIG. 2, the exhaust pipe plasma reactor 110 includes a reaction chamber 120, a magnetic core 130 arranged to surround the reaction chamber 120, an igniter 140 for plasma ignition, and a coil wound on the magnetic core 130 and powered from the exhaust pipe reactor power source 145.

The reaction chamber 120 that is a chamber having a toroidal shape includes a gas inlet 121, a gas outlet 123 located spaced apart from the gas inlet 121, a plasma reaction unit 125 in which a plasma reaction occurs by connecting the gas inlet 121 to the gas outlet 123.

The gas inlet 121 has a shape of a short pipe extending around a straight extension axis line X1, and a front end of the gas inlet 121 is open so that an inlet 122 through which the exhaust gas is introduced, may be formed.

The gas outlet 123 has a shape of a short pipe located coaxially spaced apart from the gas inlet 121 on the extension axis line X1, and a rear end of the gas outlet 123 is open so that an outlet 124 through which the exhaust gas is discharged, may be formed.

The plasma reaction unit 125 connects the gas inlet 121 and the gas outlet 123, which are spaced apart from each other, to each other and forms a plasma treatment area A1 therein. The plasma reaction unit 125 includes a first connector portion 126 and a second connector portion 127 located spaced apart from each other at both sides of the extension axis line X1. The first connector portion 126 and the second connector portion 127 extend generally parallel to the extension axis line X1 and communicate with the gas inlet 121 and the gas outlet 123. Thus, plasma occurs along a ring-shaped discharge loop R1 as shown by a dashed line. After the exhaust gas introduced through the gas inlet 122 is treated by plasma generated in the plasma reaction unit 125, the exhaust gas is discharged through the gas outlet 124.

In the present embodiment, it will be described that the reaction chamber 120 is configured by combining a first chamber member 120a including the entire gas inlet 121, part of the first connector portion 126 and part of the second connector portion 127 connected to the gas inlet 121 with a second chamber member 120b including the gas outlet 123, and part of the first connector portion 126 and part of the second connector portion 127 connected to the gas outlet 123, and the present invention is not limited thereto.

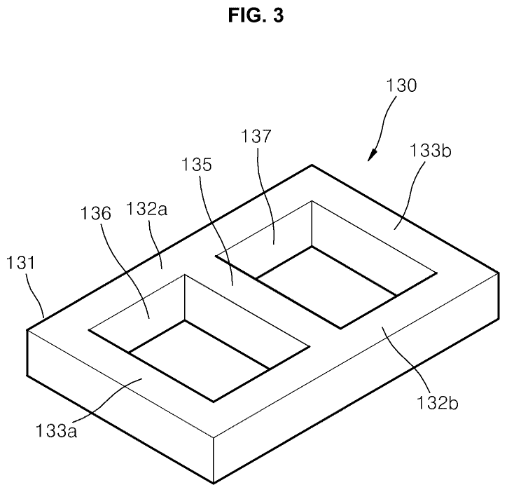

The magnetic core 130 is arranged to surround the reaction chamber 120. In the present embodiment, it will be described that the magnetic core 130 is a ferrite core generally used in an ICP generating device. FIG. 3 is a perspective view of the magnetic core 130. Referring to FIGS. 2 and 3, the magnetic core 130 includes a ring-shaped ring portion 131 that surrounds the plasma reaction unit 125 of the reaction chamber 120 from the outside, and a connector 135 that crosses an inner area of the ring portion 131.

The ring portion 131 having a rectangular ring shape is arranged perpendicular to the extension axis line X1 and surrounds the plasma reaction unit 125 of the reaction chamber 120. The ring portion 131 having a rectangular shape includes two opposite long sides 132a and 132b, and two opposite short sides 133a and 133b.

The connector 135 extends in a straight line to connect between two opposite long sides 132a and 132b of the ring portion 131. Both ends of the connector 135 are connected to centers of each of two long sides 132a and 132b. The connector 135 is arranged to pass through an aperture 128 formed between the first connector portion 126 and the second connector portion 127 of the reaction chamber 120. The inner area of the ring portion 131 is divided into a first through hole 136 and a second through hole 137 by the connector 135, and the first connector portion 126 of the reaction chamber 120 passes through the first through hole 136, and the second connector portion 127 of the reaction chamber 120 passes through the second through hole 137. Thus, the magnetic core 130 has a shape surrounding each of the first connector portion 126 and the second connector portion 127 of the reaction chamber 120 from the outside.

The igniter 140 ignites plasma by receiving power with a high voltage from the outside. In the present embodiment, it will be described that the igniter 140 is located adjacent to the gas inlet 121 in the plasma reaction unit 125 of the reaction chamber 120, and the present invention is not limited thereto.

The coil (not shown) is wound on the magnetic core 130 and is connected to the power source 180. The coil (not shown) forms an induced magnetic flux in the magnetic core 130 by receiving radio frequency alternating current power through the power source 180. An induced magnetic field is generated by the inducted magnetic flux formed in the magnetic core 130, and plasma is formed by the generated induced magnetic field.

Referring to FIG. 1, the exhaust pipe reactor power source 145 applies the radio frequency alternating current power to a coil (not shown) wound on the magnetic core (130 of FIG. 2) so that ICP may be generated in the exhaust pipe plasma reactor 110. Also, the exhaust pipe reactor power source 145 supplies power to the igniter (140 of FIG. 2).

The powder collection trap 148 is installed downstream of the exhaust pipe plasma reactor 110 on the chamber exhaust pipe 107 and collects powder contained in the exhaust gas discharged from the exhaust pipe plasma reactor 110. Since the powder collection trap 148 may be a commonly used type (for example, a particle collection device described in Korean Patent Registration No. 10-1480237, etc.), detailed descriptions thereof will be omitted. The powder collected in the powder collection trap 148 reacts with the reactive species generated in the remote plasma reactor 150 and is gasified. The powder collection trap 148 is combined with the remote plasma reactor 150 and forms a whole. A cooler may also be provided in the powder collection trap 148.

The remote plasma reactor 150 decomposes a source gas supplied from the remote plasma source gas supplier 190 by using plasma to generate a remote plasma gas including reactive species. Ingredients to be removed that are not removed from the exhaust pipe plasma reactor 110 may be additionally removed by the remote plasma gas including reactive species generated in the remote plasma reactor 150. The remote plasma gas including the reactive species generated in the remote plasma reactor 150 is supplied to the powder collection trap 148. In the present embodiment, the remote plasma reactor 150 generates excited fluorine atoms (F*), which are reactive fluorine, or excited oxygen atoms (O*), which are reactive oxygen, as reactive species by using plasma. In the present embodiment, it will be described that the exited fluorine atoms (F*) are generated by decomposing nitrogen trifluoride (NF₃), which is a source gas supplied from the remote plasma source gas supplier 190, by plasma in the remote plasma reactor 150. The excited fluorine atoms (F*) are generated when nitrogen trifluoride (NF₃) is decomposed by plasma in the remote plasma reactor 150. In the present embodiment, it will be described that the excited oxygen atoms (O*) are generated by decomposing oxygen (O₂) as a source gas supplied from the remote plasma source gas supplier 190 by plasma in the remote plasma reactor 150. In the present embodiment, it will be described that the remote plasma reactor 150 is combined with the powder collection trap 148 and forms a whole, and the present invention is not limited thereto. The remote plasma reactor 150 may communicate with the powder collection trap 148 through a pipe, and this also belongs to the scope of the present invention.

In the present embodiment, it will be described that the remote plasma reactor 150 is an ICP reactor using ICP. In the present embodiment, it will be described that the remote plasma reactor 150 uses ICP, and the present invention is not limited thereto. In the present invention, the remote plasma reactor includes all types of plasma reactors (for example, a plasma reactor using capacitively coupled plasma (CCP)) that generate a plasma reaction, and this also belongs to the scope of the present invention.

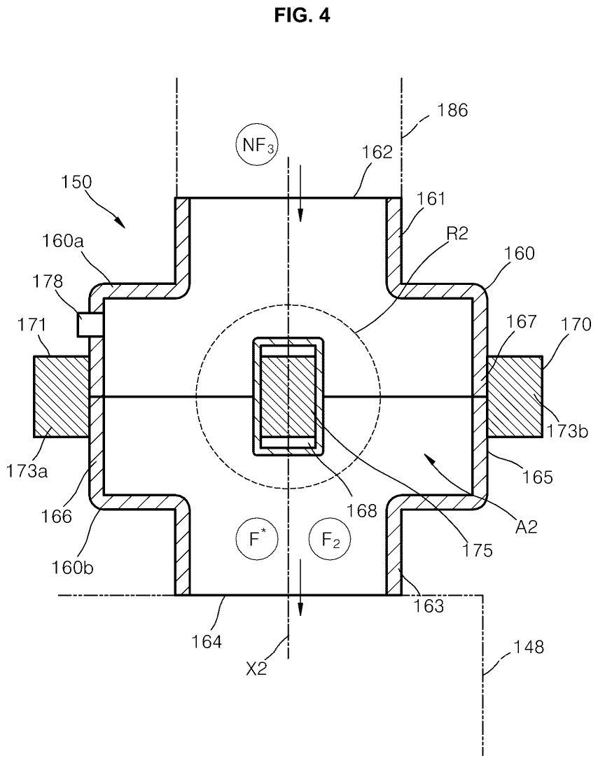

FIG. 4 is a longitudinal cross-sectional view of a schematic configuration of the remote plasma reactor 150. Referring to FIG. 4, the remote plasma reactor 150 includes a reaction chamber 160, a magnetic core 170 arranged to surround the reaction chamber 160, an igniter 178 for plasma ignition, and a coil (not shown) wound on the magnetic core 170 and powered from the remote reactor power source 180.

The reaction chamber 160 that is a chamber having a toroidal shape includes a gas inlet 161, a gas outlet 163 located spaced apart from the gas inlet 161, and a plasma reactor 165, which connects the gas inlet 161 to the gas outlet 163 in which a plasma reaction occurs. The reaction chamber 160 generates excited fluorine atoms (F*) as reactive species by decomposing a NF₃ gas as a source gas supplied from the gas supplier (190 of FIG. 1) by using plasma, or generates excited oxygen atoms (O*) as reactive species by decomposing an O₂ gas as a source gas supplied from the remote plasma source gas supplier (190 of FIG. 1) by using plasma.

The gas inlet 161 has a shape of a short pipe that extends around a straight extension axis line X2, and a front end of the gas inlet 161 is open so that an inlet 162 through which gas is introduced, may be formed. The inlet 162 communicates with the remote plasma source gas supplier 190 through the gas inlet 186. Nitrogen trifluoride (NF₃) or oxygen (O₂) supplied by the remote plasma source gas supplier 190 through the inlet 162 is introduced into the reaction chamber 160.

The gas outlet 163 has a shape of a short pipe located coaxially spaced apart from the gas inlet 161 on the extension axis line X, and a rear end of the gas outlet 163 is open so that an outlet 164 through which gas is discharged, may be formed. The gas outlet 163 is directly combined with the powder collection trap (148 of FIG. 1) so that the remote plasma gas including the reactive species generated in the remote plasma reactor 150 through the outlet 164 is introduced into the powder collection trap (148 of FIG. 1).

The plasma reactor 165 connects the spaced gas inlet 161 and the gas outlet 163 to each other to form a plasma reaction area A2 in which a thermal reaction with respect to gas and a plasma reaction occur. The plasma reactor 165 includes a first connector portion 166 and a second connector portion 167 located spaced apart from each other at both sides of the extension axis line X2. The first connector portion 166 and the second connector portion 167 extend parallel to the extension axis line X2 and communicate with the gas inlet 161 and the gas outlet 163. Thus, plasma occurs in the plasma reactor 165 along a ring-shaped discharge loop R2 as shown by a dashed line.

Gas introduced through the inlet 162 is decomposed by plasma formed in the plasma reaction area A2 so that reactive species may be formed. As shown, when nitrogen trifluoride (NF₃) is introduced as a source gas through the inlet 122, nitrogen trifluoride (NF₃) is decomposed in the plasma reaction area A2 so that excited fluorine atoms (F*) and fluoride (F₂) that are reactive species may be generated. Specifically, in the plasma reaction area A2, nitrogen trifluoride (NF₃) may be decomposed as ingredients including nitrogen (N₂), fluoride (F₂), excited nitrogen atoms (N*), excited fluorine atoms (F*), and electrons (e). Although not shown, when oxygen (O₂) is introduced through the inlet 162, oxygen (O₂) is decomposed in the plasma reaction area A2 so that the excited oxygen atoms (O*) that are reactive species may be generated.

In the present embodiment, it will be described that the reaction chamber 160 is configured by combining the first chamber member 160a with the second chamber member 160b. The first chamber member 160a includes the entire gas inlet 161, part of the first connector portion 166 and part of the second connector portion 167, which are connected to the gas inlet 161. The second chamber member 160b includes the entire gas outlet 163, and part of the first connector portion 166 and part of the second connector portion 167, which are connected to the gas outlet 163.

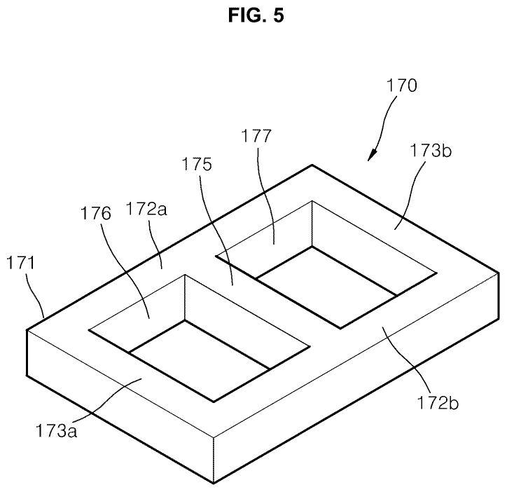

The magnetic core 170 is arranged to surround the reaction chamber 160. In the present embodiment, it will be described that the magnetic core 170 is a ferrite core generally used in the ICP generating device. FIG. 5 is a perspective view of the magnetic core 170. Referring to FIGS. 4 and 5, the magnetic core 170 includes a ring-shaped ring portion 171 surrounding the plasma reactor 165 of the reaction chamber 160 from the outside, and a connector 175 crossing an inner area of the ring portion 171.

The ring portion 171 has a generally rectangular ring shape, is arranged perpendicular to the extension axis line X2, and surrounds the plasma reaction unit 165 of the reaction chamber 160 from the outside. The rectangular ring portion 171 includes two opposite long sides 172a and 172b, and two opposite short sides 173a and 173b.

The connector 175 extends in a straight line to connect between two opposite long sides 172a and 172b of the ring portion 171. Both ends of the connector 175 are connected to centers of each of two long sides 172a and 172b. The connector 175 is arranged to pass through an aperture 168 formed between the first connector portion 166 and the second connector portion 167 of the reaction chamber 160. The inner area of the ring portion 171 is divided into a first through hole 176 and a second through hole 177 by the connector 165, and the first connector portion 166 of the reaction chamber 160 passes through the first through hole 176, and the second connector portion 167 of the reaction chamber 160 passes through the second through hole 177. Thus, the magnetic core 170 has a shape surrounding each of the first connector portion 166 and the second connector portion 167 of the reaction chamber 160 from the outside.

Referring to FIG. 4, an igniter 178 ignites plasma by receiving power of a high voltage from the remote reactor power source 180. In the present embodiment, it will be described that the igniter 178 is located adjacent to the gas inlet 161 in the plasma reaction unit 165 of the reaction chamber 160, and the present invention is not limited A coil (not shown) is wound on the magnetic core 170 and is connected to the remote reactor power source 180. The coil (not shown) forms an induced magnetic flux in the magnetic core 170 by receiving radio frequency alternating current power through the remote reactor power source 180. An induced magnetic field is generated by the inducted magnetic flux formed in the magnetic core 170, and plasma is formed by the generated induced magnetic field.

Referring to FIG. 1, the remote reactor power source 180 applies radio frequency alternating current power to the coil (not shown) wound on the magnetic core (170 of FIG. 4) so that ICP may be generated in the remote plasma reactor 150. Also, the remote reactor power source 180 supplies power to the igniter (178 of FIG. 4).

The remote plasma source gas supplier 190 stores a remote plasma source gas of reactive species generated by plasma in the remote plasma reactor 150 and supplies the stored remote plasma source gas to the remote plasma reactor 190 through the gas inlet 186. In the present embodiment, it will be described that the gas supplier 190 supplies nitrogen trifluoride (NF₃) or oxygen (O₂) as a source gas of reactive species to the remote plasma reactor 150.

Hereinafter, the operation of the exhaust gas pretreatment equipment 109 according to various processes performed in the process chamber 102 will be described in detail.

First, the operation of the exhaust gas pretreatment equipment 109 when a SiO₂ process using a process gas including a Si-containing precursor is performed in the process chamber 102, will be described as below. In the present embodiment, it will be described that Si(OC₂H₅)₄ TEOS is used as the Si-containing precursor. After the SiO₂ process is performed in the process chamber 102, an exhaust gas including unresponsive TEOS is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. TEOS contained in the exhaust gas discharged from the semiconductor process chamber 102 reacts with oxygen in the exhaust pipe plasma reactor 110 by the operation of the exhaust pipe plasma reactor 110 and forms SiO₂ that is stabilized powder. The SiO₂ powder generated in the exhaust pipe plasma reactor 110 is discharged from the exhaust pipe plasma reactor 110, flows along the chamber exhaust pipe 107 and is collected in the powder collection trap 148. Also, the exhaust pipe plasma reactor 110 decomposes fluorine (F) ingredients contained in the exhaust gas of the process chamber 102 in a plasma reaction to form excited fluorine atoms (F*) that are reactive species. Nitrogen trifluoride (NF₃) as a source gas is supplied to the remote plasma reactor 150, and the remote plasma reactor 150 decomposes NF₃ gas in a plasma reaction to generate excited fluorine atoms (F*) that are reactive species. The excited fluorine atoms (F*) generated in the exhaust pipe plasma reactor 110 and the remote plasma reactor 150 are supplied to the powder collection trap 148. In the powder collection trap 148, the SiO₂ powder reacts with the excited fluorine atoms (F*), is gasified and forms SiF₄. Thus, fluidity may be prevented from being reduced due to the SiO₂ powder accumulating in the exhaust equipment 105 including the vacuum pump 106.

Subsequently, the operation of the exhaust gas pretreatment equipment 109 when the TiO₂ process using a process gas including a Ti-containing precursor is performed in the process chamber 102, will be described as below. In the present embodiment, it will be described that Ti(OCH₂CH₃)₄ is used as the Ti-containing precursor. After the TiO₂ process is performed in the process chamber 102, the exhaust gas including unresponsive Ti(OCH₂CH₃)₄ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. Ti(OCH₂CH₃)₄ contained in the exhaust gas discharged from the semiconductor process chamber 102 reacts with oxygen in the exhaust pipe plasma reactor 110 by the operation of the exhaust pipe plasma reactor 110 to generate TiO₂ that is stabilized powder. The TiO₂ powder generated in the exhaust plasm reactor 110 is discharged from the exhaust pipe plasma reactor 110, flows along the chamber exhaust pipe 107 and is collected in the powder collection trap 148. Also, the exhaust pipe plasma reactor 110 decomposes the fluorine (F) ingredient contained in the exhaust gas of the process chamber 102 in a plasma reaction to generate excited fluorine atoms (F*) that are reactive species. Nitrogen trifluoride (NF₃) as a source gas is supplied to the remote plasma reactor 150, and the remote plasma reactor 150 composes a NF₃ gas in a plasma reaction to generate excited fluorine atoms (F*) that are reactive species. The excited fluorine atoms (F*) generated in the exhaust pipe plasma reactor 110 and the remote plasma reactor 150 are supplied to the powder collection trap 148. In the powder collection trap 148, the TiO₂ powder reacts with the excited fluorine atoms (F*), is gasified and forms TiF₄. Thus, fluidity may be prevented from being reduced due to the TiO₂ powder accumulating in the exhaust equipment 105 including the vacuum pump 106.

Subsequently, the operation of the exhaust gas pretreatment equipment 109 when the ZrO₂ process using a process gas including a Zr-containing precursor is performed in the process chamber 102, will be described as below. In the present embodiment, it will be described that (C₅H₅)Zr(N(CH₃)₂)₃ is used as the Zr-containing precursor. After the ZrO₂ process is performed in the process chamber 102, an exhaust gas including unresponsive (C₅H₅)Zr(N(CH₃)₂)₃ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. (C₅H₅)Zr(N(CH₃)₂)₃ contained in the exhaust gas discharged from the semiconductor process chamber 102 reacts with oxygen in the exhaust pipe plasma reactor 110 by the operation of the exhaust pipe plasma reactor 110 to generate ZrO₂ that is stabilized powder. The ZrO₂ powder generated in the exhaust pipe plasma reactor 110 is discharged from the exhaust pipe plasma reactor 110, flows along the chamber exhaust pipe 107 and is collected in the powder collection trap 148. Also, the exhaust pipe plasma reactor 110 decomposes fluorine (F) ingredients contained in the exhaust gas of the process chamber 102 in a plasma reaction to generate excited fluorine atoms (F*) that are reactive species. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the exhaust pipe plasma reactor 110 and the remote plasma reactor 150 are supplied to the powder collection trap 148. In the powder collection trap 148, the ZrO₂ powder reacts with the excited fluorine atoms (F*), is gasified and forms ZrF₄. Thus, fluidity may be prevented from being reduced due to the ZrO₂ powder accumulating in the exhaust equipment 105 including the vacuum pump 106.

Subsequently, the operation of the exhaust gas pretreatment equipment 109 when an HfO₂ process using a process gas including an Hf-containing precursor is performed in the process chamber 102, will be described as below. In the present embodiment, it will be described that (C₅H₅)Hf(N(CH₃)₂)₃ is used as the Hf-containing precursor. After the HfO₂ process is performed in the process chamber 102, an exhaust gas including unresponsive (C₅H₅)Hf(N(CH₃)₂)₃ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. (C₅H₅)Hf(N(CH₃)₂)₃ contained in the exhaust gas discharged from the semiconductor process chamber 102 reacts with oxygen in the exhaust pipe plasma reactor 110 by the operation of the exhaust pipe plasma reactor 110 and forms HfO₂ that is stabilized powder. The HfO₂ powder generated in the exhaust pipe plasma reactor 110 is discharged from the exhaust pipe plasma reactor 110, flows along the chamber exhaust pipe 108 and is collected in the powder collection trap 148. Also, the exhaust pipe plasma reactor 110 decomposes fluorine (F) ingredients contained in the exhaust gas of the process chamber 102 in a plasma reaction to generate excited fluorine atoms (F*) that are reactive species. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the exhaust pipe plasma reactor 110 and the remote plasma reactor 150 are supplied to the powder collection trap 148. In the powder collection trap 148, the HfO₂ powder reacts with the excited fluorine atoms (F*), is gasified, and forms HfF₄. Thus, fluidity may be prevented from being reduced due to the HfO₂ powder accumulating in the exhaust equipment 105 including the vacuum pump 106.

Subsequently, the operation of the exhaust gas pretreatment equipment 109 when a Nb₂O₅ process using a process gas including a Nb-containing precursor is performed in the process chamber 102, will be described as below. In the present embodiment, it will be described that (C₅H₅)Nb(N(CH₃)₂)₃ is used as the Nb-containing precursor. After the Nb₂O₅ process is performed in the process chamber 102, an exhaust gas including unresponsive (C₅H₅)Nb(N(CH₃)₂)₃ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. (C₅H₅)Nb(N(CH₃)₂)₃ contained in the exhaust gas discharged from the semiconductor process chamber 102 reacts with oxygen in the exhaust pipe plasma reactor 110 by the operation of the exhaust pipe plasma reactor 110 and generates Nb₂O₅ that is stabilized powder. The Nb₂O₅ powder generated in the exhaust pipe plasma reactor 110 is discharged from the exhaust pipe plasma reactor 110, flows along the chamber exhaust pipe 107 and is collected in the powder collection trap 148. Also, the exhaust pipe plasma reactor 110 decomposes fluorine (F) ingredients contained in the exhaust gas in the process chamber 102 in a plasma reaction to generate excited fluorine atoms (F*) that are reactive species. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the exhaust pipe plasma reactor 110 and the remote plasma reactor 150 are supplied to the powder collection trap 148. In the powder collection trap 148, the Nb₂O₅ powder reacts with the excited fluorine atoms (F*), is gasified and forms NbF₅. Thus, fluidity may be prevented from being reduced due to the Nb₂O₅ powder accumulating in the exhaust equipment 105 including the vacuum pump 106.

Subsequently, the operation of the exhaust gas pretreatment equipment 109 when a Ta₂O₅ process using a process gas including a Ta-containing precursor is performed in the semiconductor process chamber 102, will be described as below. In the present embodiment, it will be described that Ta(OC₂H₅)₅ is used as the Ta-containing precursor. After the Ta₂O₅ process is performed in the semiconductor process chamber 102, the exhaust gas including unresponsive Ta(OC₂H₅)₅ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. Ta(OC₂H₅)₅ contained in the exhaust gas discharged from the semiconductor process chamber 102 reacts with oxygen in the exhaust pipe plasma reactor 110 by the operation of the exhaust pipe plasma reactor 110 and generates Ta₂O₅ that is stabilized powder. The Ta₂O₅ powder generated in the exhaust pipe plasma reactor 110 is discharged from the exhaust pipe plasma reactor 110, flows along the chamber exhaust pipe 107 and is collected in the powder collection trap 148. Also, the exhaust pipe plasma reactor 110 decomposes fluorine (F) ingredients contained in the exhaust gas in the process chamber 102 in a plasma reaction to generate excited fluorine atoms (F*) that are reactive species. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the exhaust pipe plasma reactor 110 and the remote plasma reactor 150 are supplied to the powder collection trap 148. In the powder collection trap 148, the Ta₂O₅ powder reacts with the excited fluorine atoms (F*), is gasified and forms TaF5. Thus, fluidity may be prevented from being reduced due to the Ta₂O₅ powder accumulating in the exhaust equipment 105 including the vacuum pump 106.

Subsequently, the operation of the exhaust gas pretreatment equipment 109 when the ACL process is performed in the process chamber 102, will be described as below. After the ACL process is performed in the process chamber 102, an exhaust gas including hydrogenated amorphous carbon (a-C:H) is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. a-C:H contained in the exhaust gas discharged from the semiconductor process chamber 102 is decomposed into excited carbon atoms (C*) and excited hydrogen atoms (H*) by a plasma reaction in the exhaust gas plasma reactor 110 by the operation of the exhaust pipe plasma reactor 110. The excited carbon atoms (C*) and the excited hydrogen atoms (H*) generated in the exhaust gas plasma reactor 110 are discharged from the exhaust pipe plasma reactor 110, flows along the chamber exhaust pipe 107 and is introduced into the powder collection trap 148. Also, the exhaust pipe plasma reactor 110 decomposes an O₂ gas contained in the exhaust gas of the process chamber 102 in a plasma reaction to generate excited oxygen atoms (O*) are reactive species. Oxygen (O₂) as a source gas is supplied to the remote plasma reactor 150, and the remote plasma reactor 150 decomposes the O₂ gas in a plasma reaction to generate excited oxygen atoms (O*) that are reactive species. The excited oxygen atoms (O*) generated in the exhaust pipe plasma reactor 110 and the remote plasma reactor 150 are supplied to the powder collection trap 148. In the powder collection trap 148, a substitution (oxidation) reaction occurs between the excited carbon atoms (C*), the excited hydrogen atoms (H*) and the excited oxygen atoms (O*) so that carbon dioxide (CO₂) gas, carbon monoxide (CO) gas and water vapor (H₂O) are generated. Thus, fluidity may be prevented from being reduced due to a-C:H accumulating in the exhaust equipment 105 including the vacuum pump 106.

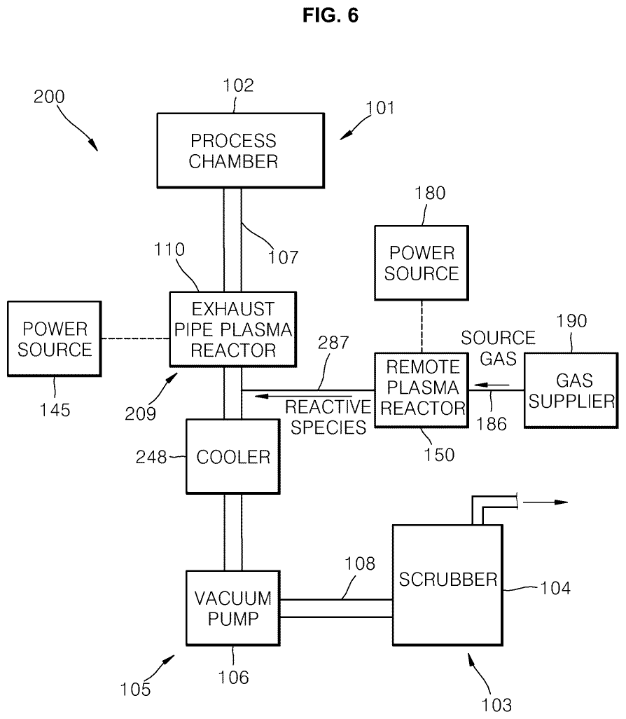

FIG. 6 is a block diagram illustrating a schematic configuration of a semiconductor manufacturing facility in which exhaust gas pretreatment equipment according to a second embodiment of the present invention is installed. Referring to FIG. 6, a semiconductor manufacturing facility 200 includes semiconductor manufacturing equipment 101 in which a semiconductor manufacturing process for manufacturing a semiconductor device is performed, gas purification equipment 103 for purifying gas discharged from the semiconductor manufacturing equipment 101, exhaust equipment 105 for discharging gas from the semiconductor manufacturing equipment 101 to allow the gas to flow into the gas purification equipment 103, and exhaust gas pretreatment equipment 209 according to the second embodiment of the present invention that prevents reduction of the fluidity of the gas by pretreating gas discharged from the semiconductor manufacturing equipment 101. The remaining configurations of the semiconductor manufacturing facility 200, except for the exhaust gas pretreatment equipment 209, are generally the same as the semiconductor manufacturing facility 100 shown in FIG. 1.

The exhaust gas pretreatment equipment 209 includes an exhaust pipe plasma reactor 110 that generates a plasma reaction with respect to an exhaust gas discharged from the semiconductor process chamber 102, an exhaust pipe reactor power source 145 that supplies power to the exhaust pipe plasma reactor 110, a cooler 248 installed on a chamber exhaust pipe 107, a remote plasma reactor 150 that generates reactive species to be supplied to the chamber exhaust pipe 107 by using plasma, a remote reactor power source 180 that supplies power to the remote plasma reactor 150, and a remote plasma source gas supplier 190 that supplies gas to the remote plasma reactor 150.

The exhaust pipe plasma reactor 110 is generally the same as the configuration of the exhaust pipe plasma reactor 110 described in the embodiment shown in FIG. 1 and thus, here, detailed descriptions thereof will be omitted.

The exhaust pipe reactor power source 145 is generally the same as the configuration of the exhaust pipe reactor power source 145 described in the embodiment shown in FIG. 1 and thus, here, detailed descriptions thereof will be omitted.

The cooler 248 is installed downstream of the exhaust pipe plasma reactor 110 on the chamber exhaust pipe 107 to decrease the temperature of the exhaust gas. The cooler 248 prevents damage of equipment due to overheating. In the present embodiment, it will be described that the cooler 248 uses water cooling using coolant, and unlike this, air cooling may also be used, and this also belongs to the scope of the present invention.

The remote plasma reactor 150 is generally the same the configuration of the remote plasma reactor 150 described in the embodiment shown in FIG. 1 and thus, here, detailed descriptions thereof will be omitted. A gas outlet (163 of FIG. 4) of the remote plasma reactor 150 communicates with the chamber exhaust pipe 107 through the discharge pipe 287. The discharge pipe is directly connected to a section between the exhaust pipe plasma reactor 110 and the cooler 248. Thus, the reactive species generated in the remote plasma reactor 150 is discharged through the outlet 164 and then flows along the discharge pipe 287, and is directly introduced into the chamber exhaust pipe 107 in the section between the exhaust pipe plasma reactor 110 and the cooler 248.

The remote reactor power source 180 is generally the same as the configuration of the remote reactor power source 180 described in the embodiment shown in FIG. 1 and thus, here, detailed descriptions thereof will be omitted.

The remote plasma source gas supplier 190 is generally the same as the configuration of the remote plasma source gas supplier 190 described in the embodiment shown in FIG. 1 and thus, here, detailed descriptions thereof will be omitted.

Hereinafter, the operation of the exhaust gas pretreatment equipment 209 according to various processes performed in the process chamber 102 will be described in detail.

First, the operation of the exhaust gas pretreatment equipment 209 when a SiO₂ process using a process gas including TEOS(Si(OC₂H₅)₄) is performed in the process chamber 102, will be described as below. After the SiO₂ process is performed in the process chamber 102, an exhaust gas including unresponsive TEOS is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. TEOS contained in the exhaust gas discharged from the semiconductor process chamber 102 reacts with oxygen in the exhaust pipe plasma reactor 110 by the operation of the exhaust pipe plasma reactor 110 and generates SiO₂ that is stabilized powder. The SiO₂ powder generated in the exhaust pipe plasma reactor 110 is discharged from the exhaust pipe plasma reactor 110 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to a section between the exhaust pipe plasma reactor 110 and the cooler 248 in the chamber exhaust pipe 107. The SiO₂ powder generated in the exhaust pipe plasma reactor 110 reacts with the excited fluorine atoms (F*) injected into the chamber exhaust pipe 107, is gasified and forms SiF₄. Thus, fluidity may be prevented from being reduced due to the SiO₂ powder accumulating in the exhaust equipment 105 including the vacuum pump 106.

Subsequently, the operation of the exhaust gas pretreatment equipment 209 when a TiO₂ process using a process gas including Ti(OCH₂CH₃)₄ is performed in the process chamber 102, will be described as below. After the TiO₂ process is performed in the process chamber 102, an exhaust gas including unresponsive Ti(OCH₂CH₃)₄ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. Ti(OCH₂CH₃)₄ contained in the exhaust gas discharged from the semiconductor process chamber 102 reacts with oxygen in the exhaust pipe plasma reactor 110 by the operation of the exhaust pipe plasma reactor 110 and generates TiO₂ that is stabilized powder. The TiO₂ powder generated in the exhaust pipe plasma reactor 110 is discharged from the exhaust pipe plasma reactor 110 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to a section between the exhaust pipe plasma reactor 110 and the cooler 248 in the chamber exhaust pipe 107. The TiO₂ powder generated in the exhaust pipe plasma reactor 110 reacts with the excited fluorine atoms (F*) injected into the chamber exhaust pipe 107, is gasified and forms TiF₄. Thus, fluidity may be prevented from being reduced due to the TiO₂ powder accumulating in the exhaust equipment 105 including the vacuum pump 106.

Subsequently, the operation of the exhaust gas pretreatment equipment 209 when a ZrO₂ process using a process gas including (C₅H₅)Zr(N(CH₃)₂)₃ is performed in the process chamber 102, will be described as below. After the ZrO₂ process is performed in the process chamber 102, an exhaust gas including unresponsive (C₅H₅)Zr(N(CH₃)₂)₃ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. (C₅H₅)Zr(N(CH₃)₂)₃ contained in the exhaust gas discharged from the semiconductor process chamber 102 reacts with oxygen in the exhaust pipe plasma reactor 110 by the operation of the exhaust pipe plasma reactor 110 to generate ZrO₂ that is stabilized powder. The ZrO₂ powder generated in the exhaust pipe plasma reactor 110 is discharged from the exhaust pipe plasma reactor 110 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to the section between the exhaust pipe plasma reactor 110 and the cooler 248 in the chamber exhaust pipe 107. The ZrO₂ powder generated in the exhaust pipe plasma reactor 110 reacts with the excited fluorine atoms (F*) injected into the chamber exhaust pipe 107, is gasified and forms ZrF₄. Thus, fluidity may be prevented from being reduced due to the ZrO₂ powder accumulating in the exhaust equipment 105 including the vacuum pump 106.

Subsequently, the operation of the exhaust gas pretreatment equipment 209 when an HfO₂ process using a process gas including (C₅H₅)Hf(N(CH₃)₂)₃ is performed in the process chamber 102, will be described as below. After the HfO₂ process is performed in the process chamber 102, an exhaust gas including unresponsive (C₅H₅)Hf(N(CH₃)₂)₃ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. (C₅H₅)Hf(N(CH₃)₂)₃ contained in the exhaust gas discharged from the semiconductor process chamber 102 reacts with oxygen in the exhaust pipe plasma reactor 110 by the operation of the exhaust pipe plasma reactor 110 and forms HfO₂ that is stabilized powder. The HfO₂ powder generated in the exhaust pipe plasma reactor 110 is discharged from the exhaust pipe plasma reactor 110 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to the section between the exhaust pipe plasma reactor 110 and the cooler 248 in the chamber exhaust pipe 107. The HfO₂ powder generated in the exhaust pipe plasma reactor 110 reacts with the excited fluorine atoms (F*) injected into the chamber exhaust pipe 107, is gasified, and forms HfF₄. Thus, fluidity may be prevented from being reduced due to the HfO₂ powder accumulating in the exhaust equipment 105 including the vacuum pump 106.

Subsequently, the operation of the exhaust gas pretreatment equipment 209 when a Nb₂O₅ process using a process gas including (C₅H₅)Nb(N(CH₃)₂)₃ is performed in the process chamber 102, will be described as below. After the Nb₂O₅ process is performed in the process chamber 102, an exhaust gas including unresponsive (C₅H₅)Nb(N(CH₃)₂)₃ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. (C₅H₅)Nb(N(CH₃)₂)₃ contained in the exhaust gas discharged from the semiconductor process chamber 102 reacts with oxygen in the exhaust pipe plasma reactor 110 by the operation of the exhaust pipe plasma reactor 110 and generates Nb₂O₅ that is stabilized powder. The Nb₂O₅ powder generated in the exhaust pipe plasma reactor 110 is discharged from the exhaust pipe plasma reactor 110 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to the section between the exhaust pipe plasma reactor 110 and the cooler 248 in the chamber exhaust pipe 107. The Nb₂O₅ powder generated in the exhaust pipe plasma reactor 110 reacts with the excited fluorine atoms (F*) injected into the chamber exhaust pipe 107, is gasified and forms NbF₅. Thus, fluidity may be prevented from being reduced due to the Nb₂O₅ powder accumulating in the exhaust equipment 105 including the vacuum pump 106.

Subsequently, the operation of the exhaust gas pretreatment equipment 209 when a Ta₂O₅ process using a process gas including Ta(OC₂H₅)₅ is performed in the semiconductor process chamber 102, will be described as below. After the Ta₂O₅ process is performed in the semiconductor process chamber 102, the exhaust gas including unresponsive Ta(OC₂H₅)₅ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. Ta(OC₂H₅)₅ contained in the exhaust gas discharged from the semiconductor process chamber 102 reacts with oxygen in the exhaust pipe plasma reactor 110 by the operation of the exhaust pipe plasma reactor 110 and generates Ta₂O₅ that is stabilized powder. The Ta₂O₅ powder generated in the exhaust pipe plasma reactor 110 is discharged from the exhaust pipe plasma reactor 110 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to the section between the exhaust pipe plasma reactor 110 and the cooler 248 in the chamber exhaust pipe 107. The Ta₂O₅ powder generated in the exhaust pipe plasma reactor 110 reacts with the excited fluorine atoms (F*) injected into the chamber exhaust pipe 108, is gasified and forms TaF₅. Thus, fluidity may be prevented from being reduced due to the Ta₂O₅ powder accumulating in the exhaust equipment 105 including the vacuum pump 106.

Subsequently, the operation of the exhaust gas pretreatment equipment 209 when the ACL process is performed in the semiconductor process chamber 102, will be described as below. After the ACL process is performed in the semiconductor process chamber 102, an exhaust gas including hydrogenated amorphous carbon (a-C:H) is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. a-C:H contained in the exhaust gas discharged from the semiconductor process chamber 102 is decomposed into excited carbon atoms (C*) and excited hydrogen atoms (H*) by a plasma reaction in the exhaust gas plasma reactor 110. The excited carbon atoms (C*) and the excited hydrogen atoms (H*) generated in the exhaust gas plasma reactor 110 are discharged from the exhaust pipe plasma reactor 110 and flows along the chamber exhaust pipe 107. Oxygen (O₂) as a source gas is supplied to the remote plasma reactor 150, and the remote plasma reactor 150 decomposes the O₂ gas in a plasma reaction to generate excited oxygen atoms (O*) that are reactive species. The excited oxygen atoms (O*) generated in the remote plasma reactor 150 are supplied to the section between the exhaust pipe plasma reactor 110 and the cooler 248 in the chamber exhaust pipe 107. A substitution (oxidation) reaction occurs between the excited carbon atoms (C*) and the excited hydrogen atoms (H*) that are generated in the exhaust pipe plasma reactor 110 and the excited oxygen atoms (O*) injected into the chamber exhaust pipe 107 so that carbon dioxide (CO₂) gas, carbon monoxide (CO) gas and water vapor (H₂O) are generated. Thus, fluidity may be prevented from being reduced due to a-C:H accumulating in the exhaust equipment 105 including the vacuum pump 106.

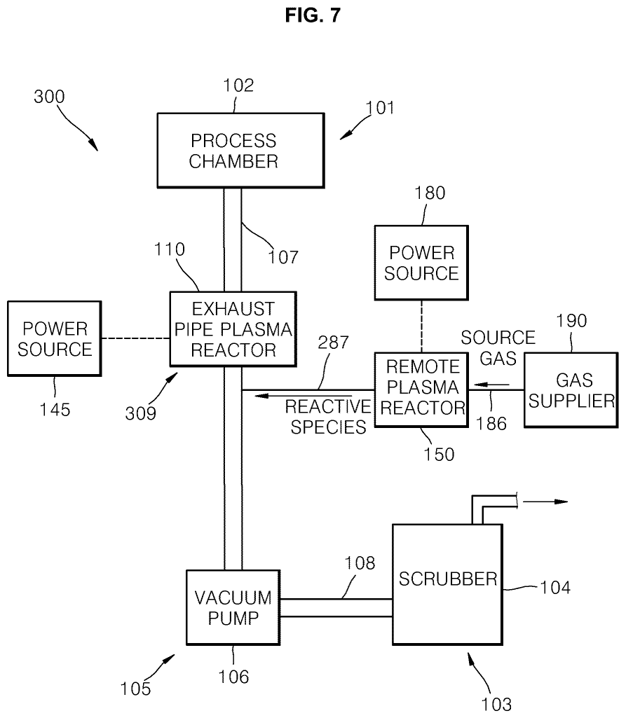

FIG. 7 is a block diagram illustrating a schematic configuration of a semiconductor manufacturing facility in which exhaust gas pretreatment equipment according to a third embodiment of the present invention is installed. Referring to FIG. 7, a semiconductor manufacturing facility 300 includes semiconductor manufacturing equipment 101 in which a semiconductor manufacturing process for manufacturing a semiconductor device is performed, gas purification equipment 103 for purifying gas discharged from the semiconductor manufacturing equipment 101, exhaust equipment 105 for discharging gas from the semiconductor manufacturing equipment 101 to allow the gas to flow into the gas purification equipment 103, and exhaust gas pretreatment equipment 309 according to the third embodiment of the present invention that prevents reduction of the fluidity of the gas by pretreating gas discharged from the semiconductor manufacturing equipment 101. The remaining configurations of the semiconductor manufacturing facility 300, except for the exhaust gas pretreatment equipment 309, are generally the same as the semiconductor manufacturing facility 100 shown in FIG. 1.

The exhaust gas pretreatment equipment 309 includes an exhaust pipe plasma reactor 110 that generates a plasma reaction with respect to the exhaust gas discharged from the semiconductor process chamber 102, an exhaust pipe reactor power source 145 that supplies power to the exhaust pipe plasma reactor 110, a remote plasma reactor 150 that generates reactive species to be supplied to the chamber exhaust pipe 107 by using plasma, a remote reactor power source 180 that supplies power to the remote plasma reactor 150, and a remote plasma source gas supplier 190 that supplies gas to the remote plasma reactor 150. The exhaust gas pretreatment equipment 309 is the configuration in which the cooler 248 is excluded from the exhaust gas pretreatment equipment 209 shown in FIG. 2, and does not require cooling compared to the exhaust gas pretreatment equipment 209 shown in FIG. 2 so that energy consumption efficiency in the operation of the exhaust gas pretreatment equipment 309 is improved. The operation of the exhaust gas pretreatment equipment 309 is generally the same as the operation of the exhaust gas pretreatment equipment 209 described in the embodiment of FIG. 6.

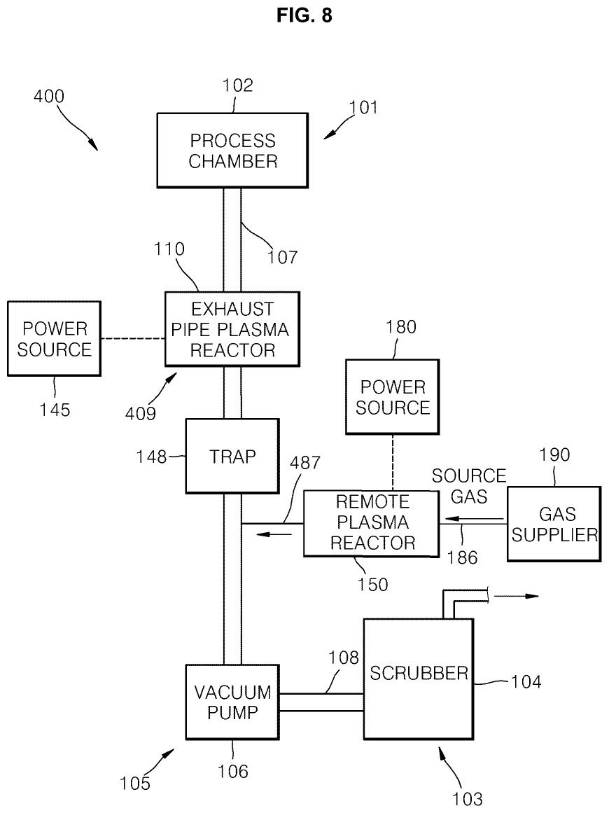

FIG. 8 is a block diagram illustrating a schematic configuration of a semiconductor manufacturing facility in which exhaust gas pretreatment equipment according to a fourth embodiment of the present invention is installed. Referring to FIG. 8, a semiconductor manufacturing facility 400 includes semiconductor manufacturing equipment 101 in which a semiconductor manufacturing process for manufacturing a semiconductor device is performed, gas purification equipment 103 for purifying gas discharged from the semiconductor manufacturing equipment 101, exhaust equipment 105 for discharging gas from the semiconductor manufacturing equipment 101 to allow the gas to flow into the gas purification equipment 103, and exhaust gas pretreatment equipment 409 according to the fourth embodiment of the present invention that prevents reduction of the fluidity of the gas by pretreating gas discharged from the semiconductor manufacturing equipment 101. The remaining configurations of the semiconductor manufacturing facility 400, except for the exhaust gas pretreatment equipment 409, are generally the same as the semiconductor manufacturing facility 100 shown in FIG. 1.

The exhaust gas pretreatment equipment 409 includes an exhaust pipe plasma reactor 110 that generates a plasma reaction with respect to an exhaust gas discharged from the semiconductor process chamber 102, an exhaust pipe reactor power source 145 that supplies power to the exhaust pipe plasma reactor 110, a powder collection trap 148 that is installed on the chamber exhaust pipe 107 and collects powder, a remote plasma reactor 150 that generates reactive species to be supplied to the chamber exhaust pipe 107 by using plasma, a remote reactor power source 180 that supplies power to the remote plasma reactor 150, and a remote plasma source gas supplier 190 that supplies gas to the remote plasma reactor 150.

The exhaust pipe plasma reactor 110 is generally the same as the configuration of the exhaust pipe plasma reactor 110 described in the embodiment shown in FIG. 1 and thus, here, detailed descriptions thereof will be omitted.

The exhaust pipe reactor power source 145 is generally the same as the configuration of the exhaust pipe reactor power source 145 described in the embodiment shown in FIG. 1 and thus, here, detailed descriptions thereof will be omitted.

The powder collection trap 148 is generally the same as the configuration of the powder collection trap 148 described in the embodiment shown in FIG. 1 and thus, here, detailed descriptions thereof will be omitted.

The remote plasma rector 150 is generally the same as the configuration of the remote plasma reactor 150 described in the embodiment shown in FIG. 1 and thus, here, detailed descriptions thereof will be omitted. The gas outlet (163 of FIG. 4) of the remote plasma reactor 150 communicates with the chamber exhaust pipe 107 through a discharge pipe 487. The discharge pipe 487 is directly connected to a section between the powder collection trap 148 and the vacuum pump 106 in the chamber exhaust pipe 107. Thus, reactive species generated in the remote plasma reactor 150 are discharged through the outlet 164 and then flow along the discharge pipe 487 and are directly introduced into the chamber exhaust pipe 107 in the section between the powder collection trap 148 and the vacuum pump 106.

The remote reactor power source 180 is generally the same as the configuration of the remote reactor power source 180 described in the embodiment shown in FIG. 1 and thus, here, detailed descriptions thereof will be omitted.

The remote plasma source gas supplier 190 is generally the same as the configuration of the remote plasma source gas supplier 190 described in the embodiment shown in FIG. 1 and thus, here, detailed descriptions thereof will be omitted.

Hereinafter, the operation of the exhaust gas pretreatment equipment 409 according to various processes performed in the semiconductor process chamber 102 will be described in detail.

First, the operation of the exhaust gas pretreatment equipment 409 when a SiO₂ process using a process gas including TEOS(Si(OC₂H₅)₄) is performed in the semiconductor process chamber 102, will be described as below. After the SiO₂ process is performed in the semiconductor process chamber 102, an exhaust gas including unresponsive TEOS is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. TEOS contained in the exhaust gas discharged from the semiconductor process chamber 102 reacts with oxygen in the exhaust pipe plasma reactor 110 by the operation of the exhaust pipe plasma reactor 110 and generates SiO₂ that is stabilized powder. The SiO₂ powder generated in the exhaust pipe plasma reactor 110 is discharged from the exhaust pipe plasma reactor 110, flows along the chamber exhaust pipe 107 and is collected in the powder collection trap 148, and uncollected SiO₂ powder that is not collected in the powder collection trap 148 passes through the powder collection trap 148, flows along the chamber exhaust pipe 107. Nitrogen trifluoride (NF₃) as a source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated in the remote plasma reactor 150 are supplied to a section between the powder collection trap 148 and the vacuum pump 106 in the chamber exhaust pipe 107. The uncollected SiO₂ powder passing through the powder collection trap 148 reacts with excited fluorine atoms (F*) injected into the chamber exhaust pipe 107, is gasified and forms SiF₄. Thus, fluidity may be prevented from being reduced due to the uncollected SiO₂ powder accumulating in the exhaust equipment 105 including the vacuum pump 106.

Subsequently, the operation of the exhaust gas pretreatment equipment 409 when a TiO₂ process using a process gas including Ti(OCH₂CH₃)₄ is performed in the semiconductor process chamber 102, will be described as below. After the TiO₂ process is performed in the semiconductor process chamber 102, the exhaust gas including unresponsive Ti(OCH₂CH₃)₄ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. Ti(OCH₂CH₃)₄ contained in the exhaust gas discharged from the semiconductor process chamber 102 reacts with oxygen in the exhaust pipe plasma reactor 110 by the operation of the exhaust pipe plasma reactor 110 and generates TiO₂ that is stabilized powder. The TiO₂ powder generated in the exhaust pipe plasma reactor 110 is discharged from the exhaust pipe plasma reactor 110, flows along the chamber exhaust pipe 107 and is collected in the powder collection trap 148, and uncollected TiO₂ powder that is not collected in the powder collection trap 148 passes through the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated in the exhaust pipe plasma reactor 110 are supplied to the section between the powder collection trap 148 and the vacuum pump 106 in the chamber exhaust pipe 107. The uncollected TiO₂ powder passing through the powder collection trap 148 reacts with the excited fluorine atoms (F*) injected into the chamber exhaust pipe 107, is gasified and forms TiF₄. Thus, fluidity may be prevented from being reduced due to the uncollected TiO₂ powder accumulating in the exhaust equipment 105 including the vacuum pump 106.

Subsequently, the operation of the exhaust gas pretreatment equipment 409 when a ZrO₂ process using a process gas including (C₅H₅)Zr(N(CH₃)₂)₃ is performed in the semiconductor process chamber 102, will be described as below. After the ZrO₂ process is performed in the semiconductor process chamber 102, an exhaust gas including unresponsive (C₅H₅)Zr(N(CH₃)₂)₃ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. (C₅H₅)Zr(N(CH₃)₂)₃ contained in the exhaust gas discharged from the semiconductor process chamber 102 reacts with oxygen in the exhaust pipe plasma reactor 110 by the operation of the exhaust pipe plasma reactor 110 and generates ZrO₂ that is stabilized powder. The ZrO₂ powder generated in the exhaust pipe plasma reactor 110 is discharged from the exhaust pipe plasma reactor 110, flows along the chamber exhaust pipe 107 and is collected in the powder collection trap 148, and uncollected ZrO₂ powder that is not collected in the powder collection trap 148 passes through the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated in the remote plasma reactor 150 are supplied to the section between the powder collection trap 148 and the vacuum pump 106 in the chamber exhaust pipe 107. The uncollected ZrO₂ powder passing through the powder collection trap 148 reacts with the excited fluorine atoms (F*) injected into the chamber exhaust pipe 107, is gasified and forms ZrF₄. Thus, fluidity may be prevented from being reduced due to the uncollected ZrO₂ powder accumulating in the exhaust equipment 105 including the vacuum pump 106.

Subsequently, the operation of the exhaust gas pretreatment equipment 409 when an HfO₂ process using a process gas including (C₅H₅)Hf(N(CH₃)₂)₃ is performed in the semiconductor process chamber 102, will be described as below. After the HfO₂ process is performed in the semiconductor process chamber 102, an exhaust gas including unresponsive (C₅H₅)Hf(N(CH₃)₂)₃ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. (C₅H₅)Hf(N(CH₃)₂)₃ contained in the exhaust gas discharged from the semiconductor process chamber 102 reacts with oxygen in the exhaust pipe plasma reactor 110 by the operation of the exhaust pipe plasma reactor 110 and generates HfO₂ that is stabilized powder. The HfO₂ powder generated in the exhaust pipe plasma reactor 110 is discharged from the exhaust pipe plasma reactor 110, flows along the chamber exhaust pipe 107 and is collected in the powder collection trap 148, and uncollected HfO₂ powder that is not collected in the powder collection trap 148 passes through the powder collection trap 148 and flows along the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated in the remote plasma reactor 150 are supplied to the section between the powder collection trap 148 and the vacuum pump 106 in the chamber exhaust pipe 107. The uncollected HfO₂ powder passing the powder collection trap 148 reacts with the excited fluorine atoms (F*) injected into the chamber exhaust pipe 107, is gasified and forms HfF₄. Thus, fluidity may be prevented from being reduced due to the HfO₂ powder accumulating in the exhaust equipment 105 including the vacuum pump 106.

Subsequently, the operation of the exhaust gas pretreatment equipment 409 when a Nb₂05 process using a process gas including (C₅H₅)Nb(N(CH₃)₂)₃ is performed in the semiconductor process chamber 102, will be described as below. After the Nb₂O₅ process is performed in the process chamber 102, the exhaust gas including unresponsive (C₅H₅)Nb(N(CH₃)₂)₃ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. (C₅H₅)Nb(N(CH₃)₂)₃ contained in the exhaust gas discharged from the semiconductor process chamber 102 reacts with oxygen in the exhaust pipe plasma reactor 110 by the operation of the exhaust pipe plasma reactor 110 and generates Nb₂O₅ that is stabilized powder. The Nb₂O₅ powder generated in the exhaust pipe plasma reactor 110 is discharged from the exhaust pipe plasma reactor 110, flows along the chamber exhaust pipe 107, and is collected in the powder collection trap 148, and uncollected Nb₂05 powder that is not collected in the powder collection trap 148 passes through the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated in the remote plasma reactor 150 are supplied to the section between the powder collection trap 148 and the vacuum pump 106 in the chamber exhaust pipe 107. The uncollected Nb₂O₅ powder passing through the power collection trap 148 reacts with the excited fluorine atoms (F*) injected into the chamber exhaust pipe 107, is gasified and forms NbF₅. Thus, fluidity may be prevented from being reduced due to the Nb₂O₅ powder accumulating in the exhaust equipment 105 including the vacuum pump 106.

Subsequently, the operation of the exhaust gas pretreatment equipment 409 when a Ta₂O₅ process using a process gas including Ta(OC₂H₅)₅ is performed in the semiconductor process chamber 102, will be described as below. After the Ta₂O₅ process is performed in the semiconductor process chamber 102, an exhaust gas including unresponsive Ta(OC₂H₅)₅ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. Ta(OC₂H₅)₅ contained in the exhaust gas discharged from the semiconductor process chamber 102 reacts with oxygen in the exhaust pipe plasma reactor 110 by the operation of the exhaust pipe plasma reactor 110 and generates Ta₂O₅ that is stabilized powder. The Ta₂O₅ powder generated in the exhaust pipe plasma reactor 110 is discharged from the exhaust pipe plasma reactor 110, flows along the chamber exhaust pipe 107 and is collected in the powder collection trap 148, and uncollected Ta₂O₅ powder that is not collected in the powder collection trap 148 passes through the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated in the remote plasma reactor 150 are supplied to the section between the powder collection trap 148 and the vacuum pump 106 in the chamber exhaust pipe 107. The uncollected Ta₂05 powder passing through the powder collection trap 148 reacts with the excited fluorine atoms (F) injected into the chamber exhaust pipe 107, is gasified and forms TaF5. Thus, fluidity may be prevented from being reduced due to the Ta₂O₅ powder accumulating in the exhaust equipment 105 including the vacuum pump 106.

Subsequently, the operation of the exhaust gas pretreatment equipment 409 when an ACL process is performed in the semiconductor process chamber 102, will be described as below. After the ACL process is performed in the semiconductor process chamber 102, the exhaust gas including hydrogenated amorphous carbon (a-C:H) is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. a-C:H contained in the exhaust gas discharged from the semiconductor process chamber 102 is decompose into the excited carbon atoms (C*) and the excited hydrogen atoms (H*) by a plasma reaction in the exhaust pipe plasma reactor 110. The excited carbon atoms (C*) and the excited hydrogen atoms (H*) generated in the exhaust pipe plasma reactor 110 is discharged from the exhaust pipe plasma reactor 110, flows along the chamber exhaust pipe 107 and passes through the powder collection trap 148. Oxygen (O₂) as a source gas is supplied to the remote plasma reactor 150, and the remote plasma reactor 150 decomposes the O₂ gas in a plasma reaction and generates excited oxygen atoms (O*) that are reactive species. The excited oxygen atoms (O*) generated in the remote plasma reactor 150 are supplied to the section between the powder collection chamber 148 and the vacuum pump 106. A substitution (oxidation) reaction occurs between the excited caron atoms (C*) passing through the powder collection trap 148, the excited hydrogen atoms (H*), and the excited oxygen (O*) injected into the chamber exhaust pipe 107 so that carbon dioxide (CO2) gas, carbon oxide (CO) and water vapor (H₂O) are generated. Thus, fluidity may be prevented from being reduced due to a-C:H accumulating in the exhaust equipment 105 including the vacuum pump 106.

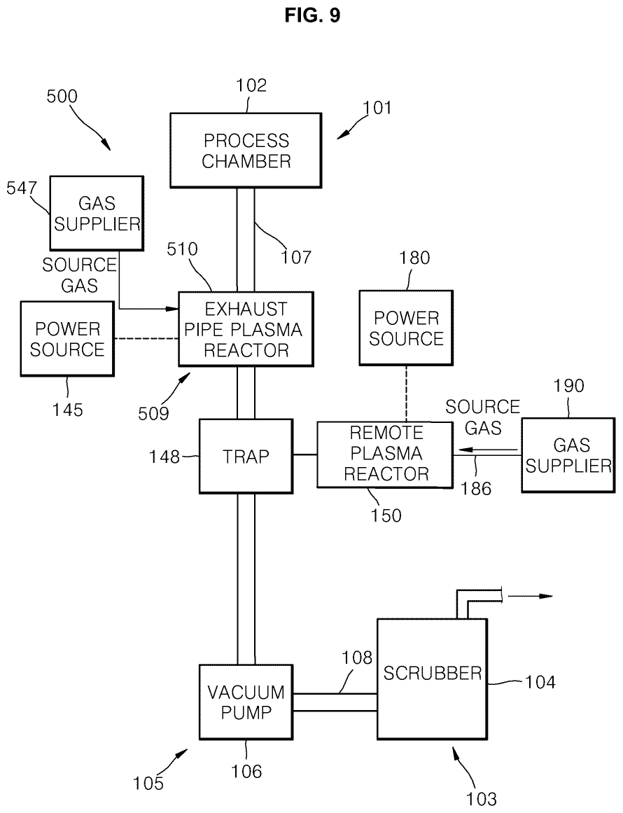

FIG. 9 is a block diagram illustrating a schematic configuration of a semiconductor manufacturing facility in which exhaust gas pretreatment equipment according to a fifth embodiment of the present invention is installed. Referring to FIG. 9, a semiconductor manufacturing facility 500 includes semiconductor manufacturing equipment 101 in which a semiconductor manufacturing process for manufacturing a semiconductor device is performed, gas purification equipment 103 for purifying gas discharged from the semiconductor manufacturing equipment 101, exhaust equipment 105 for discharging the gas from the semiconductor manufacturing equipment 101 to allow the gas to flow into the gas purification equipment 103, and exhaust gas pretreatment equipment 509 according to the fifth embodiment of the present invention that prevents reduction of the fluidity of the gas by pretreating the gas discharged from the semiconductor manufacturing equipment 101. The remaining configurations of the semiconductor manufacturing facility 500, except for the exhaust gas pretreatment equipment 509, are generally the same as the semiconductor manufacturing facility 100 shown in FIG. 1, and thus, here, only the exhaust gas pretreatment equipment 509 will be described.

The exhaust gas pretreatment equipment 509 includes an exhaust pipe plasma reactor 510 for generating a plasma reaction with respect to an exhaust gas discharged from the semiconductor process chamber 102, an exhaust pipe reactor power source 145 for supplying power to the exhaust pipe plasma reactor 110, an exhaust pipe plasma source gas supplier 547 for supplying a source gas to the exhaust pipe plasma reactor 110, a powder collection trap 148 installed on the chamber exhaust pipe 107 to collect powder, a remote plasma reactor 150 for generating reactive species to be supplied to the powder collection trap 148 by using plasma, a remote reactor power source 180 for supplying power to the remote plasma reactor 150, and a remote plasma source gas supplier 190 for supplying a source gas to the remote plasma reactor 150.

The exhaust pipe plasma reactor 510 receives an exhaust pipe plasma source gas from the exhaust pipe plasma source gas supplier 547. The remaining configurations except for the configuration of the exhaust pipe plasma reactor 510 that receives the exhaust pipe plasma source gas from the exhaust pipe plasma source gas supplier 547 are generally the same as the semiconductor manufacturing facility 100 shown in FIG. 1 and thus, here, detailed descriptions thereof will be omitted.

The exhaust pipe reactor power source 145 is generally the same as the configuration of the exhaust pipe reactor power source 145 described in the embodiment shown in FIG. 1 and thus, here, detailed descriptions thereof will be omitted.

The exhaust pipe plasma source gas supplier 547 stores the exhaust pipe plasma source gas supplied to the exhaust pipe plasma reactor 510 and supplies the stored exhaust pipe plasma source gas to the exhaust pipe plasma reactor 510. In the present embodiment, it will be described that the exhaust pipe plasma source gas supplier 547 supplies nitrogen trifluoride (NF₃) or oxygen (O₂) to the exhaust pipe plasma reactor 510.

The powder collection trap 148 is generally the same as the configuration of the powder collection trap 148 described in the embodiment shown in FIG. 1 and thus, here, detailed descriptions thereof will be omitted.

The remote plasma reactor 150 is generally the same as the remote plasma reactor 150 described in the embodiment shown in FIG. 1 and thus, here, detailed descriptions thereof will be omitted.

The remote reactor power source 180 is generally the same as the configuration of the remote reactor power source 180 described in the embodiment shown in FIG. 1 and thus, here, detailed descriptions thereof will be omitted.

The remote plasma source gas supplier 190 is generally the same as the configuration of the remote plasma source gas supplier 190 described in the embodiment shown in FIG. 1 and thus, here, detailed descriptions thereof will be omitted.

Hereinafter, the operation of the exhaust gas pretreatment equipment 509 according to various processes performed in the semiconductor process chamber 102 will be described in detail. The exhaust gas pretreatment equipment 509 may operate in the following three pretreatment examples.

### [Pretreatment Example 1]

In Pretreatment example 1, all of the exhaust pipe plasma reactor 510 and the remote plasma reactor 150 are used to generate stabilized powder by oxidation.

First, the operation of the exhaust gas pretreatment equipment 509 when a SiO₂ process using a process gas including TEOS(Si(OC₂H₅)₄) is performed in the semiconductor process chamber 102, will be described as below. After the SiO₂ process is performed in the semiconductor process chamber 102, an exhaust gas including unresponsive TEOS is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. TEOS contained in the exhaust gas discharged from the semiconductor process 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates SiO₂ that is stabilized powder. The SiO₂ powder generated in the exhaust pipe plasma reactor 510 is discharged from the exhaust pipe plasma reactor 510, flows along the chamber exhaust pipe 107 and is collected in the powder collection trap 148. Also, the remote plasma reactor 150 generates excited oxygen atoms (O*) by receiving oxygen from the remote plasma source gas supplier 190 and supplies the generated excited oxygen atoms (O*) to the powder collection trap 148. SiO₂ that is stabilized powder is generated in the powder collection trap 148 by reacting TEOS contained in the exhaust gas in the power collected trap 148 with the excited oxygen atoms (O*) supplied from the remote plasma reactor 150 and is collected in the powder collection trap 148. By collecting as much powder as possible in the powder collection trap 148, the amount of powder flowing into the vacuum pump 106 is minimized.

Subsequently, the operation of the exhaust gas pretreatment equipment 509 when the TiO₂ process using a process gas including Ti(OCH₂CH₃)₄ is performed in the semiconductor process chamber 102, will be described as below. After the TiO₂ process is performed in the semiconductor process chamber 102, the exhaust gas including unresponsive Ti(OCH₂CH₃)₄ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. Ti(OCH₂CH₃)₄ contained in the exhaust gas discharged from the semiconductor process chamber 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates TiO₂ that is stabilized powder. The TiO₂ powder generated in the exhaust pipe plasm reactor 510 is discharged from the exhaust pipe plasma reactor 510, flows along the chamber exhaust pipe 107 and is collected in the powder collection trap 148. Also, the remote plasma reactor 150 generates excited oxygen atoms (O*) by receiving oxygen from the remote plasma source gas supplier 190 and is supplied to the powder collection trap 148. TiO₂ that is stabilized powder is generated in the powder collection trap 148 by reacting Ti(OCH₂CH₃)₄ contained in the exhaust gas with the excited oxygen atoms (O*) supplied from the remote plasma reactor 150 and is collected in the powder collection trap 148. By collecting as much powder as possible in the powder collection trap 148, the amount of powder flowing into the vacuum pump 106 is minimized.

Subsequently, the operation of the exhaust gas pretreatment equipment 509 when the ZrO₂ process using a process gas including (C₅H₅)Zr(N(CH₃)₂)₃ is performed in the semiconductor process chamber 102, will be described as below. After the ZrO₂ process is performed in the semiconductor process chamber 102, the exhaust gas including unresponsive (C₅H₅)Zr(N(CH₃)₂)₃ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. (C₅H₅)Zr(N(CH₃)₂)₃ contained in the exhaust gas discharged from the semiconductor process chamber 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates ZrO₂ that is stabilized powder. The ZrO₂ powder generated in the exhaust pipe plasm reactor 510 is discharged from the exhaust pipe plasma reactor 510, flows along the chamber exhaust pipe 107 and is collected in the powder collection trap 148. Also, the remote plasma reactor 150 generates excited oxygen atoms (O*) by receiving oxygen from the remote plasma source gas supplier 190 and are supplied to the powder collection trap 148. ZrO₂ that is stabilized powder is generated in the powder collection trap 148 by reacting (C₅H₅)Zr(N(CH₃)₂)₃ contained in the exhaust gas with the excited oxygen atoms (O*) supplied from the remote plasma reactor 150 and is collected in the powder collection trap 148. By collecting as much powder as possible in the powder collection trap 148, the amount of powder flowing into the vacuum pump 106 is minimized.

Subsequently, the operation of the exhaust gas pretreatment equipment 509 when the HfO₂ process using a process gas including (C₅H₅)Hf(N(CH₃)₂)₃ is performed in the semiconductor process chamber 102, will be described as below. After the HfO₂ process is performed in the semiconductor process chamber 102, the exhaust gas including unresponsive (C₅H₅)Hf(N(CH₃)₂)₃ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. (C₅H₅)Hf(N(CH₃)₂)₃ contained in the exhaust gas discharged from the semiconductor process chamber 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates HfO₂ that is stabilized powder. The HfO₂ powder generated in the exhaust pipe plasm reactor 510 is discharged from the exhaust pipe plasma reactor 510, flows along the chamber exhaust pipe 107 and is collected in the powder collection trap 148. Also, the remote plasma reactor 150 generates excited oxygen atoms (O*) by receiving oxygen from the remote plasma source gas supplier 190 and is supplied to the powder collection trap 148. HfO₂ that is stabilized powder is generated in the powder collection trap 148 by reacting (C₅H₅)Hf(N(CH₃)₂)₃ contained in the exhaust gas with the excited oxygen atoms (O*) supplied from the remote plasma reactor 150 and is collected in the powder collection trap 148. By collecting as much powder as possible in the powder collection trap 148, the amount of powder flowing into the vacuum pump 106 is minimized.

Subsequently, the operation of the exhaust gas pretreatment equipment 509 when the Nb₂O₅ process using a process gas including (C₅H₅)Nb(N(CH₃)₂)₃ is performed in the semiconductor process chamber 102, will be described as below. After the Nb₂O₅ process is performed in the semiconductor process chamber 102, the exhaust gas including unresponsive (C₅H₅)Nb(N(CH₃)₂)₃ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. (C₅H₅)Nb(N(CH₃)₂)₃ contained in the exhaust gas discharged from the semiconductor process chamber 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates Nb₂O₅ that is stabilized powder. The Nb₂O₅ powder generated in the exhaust pipe plasm reactor 510 is discharged from the exhaust pipe plasma reactor 510, flows along the chamber exhaust pipe 107 and is collected in the powder collection trap 148. Also, the remote plasma reactor 150 generates excited oxygen atoms (O*) by receiving oxygen from the remote plasma source gas supplier 190 and is supplied to the powder collection trap 148. Nb₂O₅ that is stabilized powder is generated in the powder collection trap 148 by reacting (C₅H₅)Nb(N(CH₃)₂)₃ contained in the exhaust gas with the excited oxygen atoms (O*) supplied from the remote plasma reactor 150 and is collected in the powder collection trap 148. By collecting as much powder as possible in the powder collection trap 148, the amount of powder flowing into the vacuum pump 106 is minimized.

Subsequently, the operation of the exhaust gas pretreatment equipment 509 when the Ta₂O₅ process using a process gas including Ta(OC₂H₅)₅ is performed in the semiconductor process chamber 102, will be described as below. After the Ta₂O₅ process is performed in the semiconductor process chamber 102, the exhaust gas including unresponsive Ta(OC₂H₅)₅ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. Ta(OC₂H₅)₅ contained in the exhaust gas discharged from the semiconductor process chamber 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates Ta₂O₅ that is stabilized powder. The Ta₂O₅ powder generated in the exhaust pipe plasm reactor 510 is discharged from the exhaust pipe plasma reactor 510, flows along the chamber exhaust pipe 107 and is collected in the powder collection trap 148. Also, the remote plasma reactor 150 generates excited oxygen atoms (O*) by receiving oxygen from the remote plasma source gas supplier 190 and is supplied to the powder collection trap 148. Ta₂O₅ that is stabilized powder is generated in the powder collection trap 148 by reacting Ta(OC₂H₅)₅ contained in the exhaust gas with the excited oxygen atoms (O*) supplied from the remote plasma reactor 150 and is collected in the powder collection trap 148. By collecting as much powder as possible in the powder collection trap 148, the amount of powder flowing into the vacuum pump 106 is minimized.

### [Pretreatment Example 2]

In Pretreatment example 2, reactive species generated in the exhaust pipe plasma reactor 510 and the remote plasma reactor 150 are used for powder gasification.

First, the operation of the exhaust gas pretreatment equipment 509 when a SiO₂ process using a process gas including a Si-containing precursor is performed in the semiconductor process chamber 102, will be described as below. In the present embodiment, it will be described that Si(OC₂H₅)₄ TEOS is used as the Si-containing precursor. After the SiO₂ process is performed in the semiconductor process chamber 102, an exhaust gas including unresponsive TEOS is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. TEOS contained in the exhaust gas discharged from the semiconductor process chamber 102 reacts with oxygen in the exhaust pipe plasma reactor 510 by the operation of the exhaust pipe plasma reactor 510 and forms SiO₂ that is stabilized powder. The SiO₂ powder generated in the exhaust pipe plasma reactor 510 is discharged from the exhaust pipe plasma reactor 510, flows along the chamber exhaust pipe 107 and is collected in the powder collection trap 148. Also, the exhaust pipe plasma reactor 510 decomposes a NF₃ gas supplied by the exhaust pipe plasma source gas supplier 547 in a plasma reaction to form excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction to generate excited fluorine atoms (F*) that are reactive species. The excited fluorine atoms (F*) generated in the exhaust pipe plasma reactor 510 and the remote plasma reactor 150 are supplied to the powder collection trap 148. In the powder collection trap 148, the SiO₂ powder reacts with the excited fluorine atoms (F*), is gasified and forms SiF₄ . Thus, fluidity may be prevented from being reduced due to the SiO₂ powder accumulating in the exhaust equipment 105 including the vacuum pump 106.

Subsequently, the operation of the exhaust gas pretreatment equipment 509 when a TiO₂ process using a process gas including a Ti-containing precursor is performed in the semiconductor process chamber 102, will be described as below. In the present embodiment, it will be described that Ti(OCH₂CH₃)₄ is used as the Ti-containing precursor. After the TiO₂ process is performed in the semiconductor process chamber 102, the exhaust gas including unresponsive Ti(OCH₂CH₃)₄ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. Ti(OCH₂CH₃)₄ contained in the exhaust gas discharged from the semiconductor process chamber 102 reacts with oxygen in the exhaust pipe plasma reactor 510 by the operation of the exhaust pipe plasma reactor 510 to generate TiO₂ that is stabilized powder. The TiO₂ powder generated in the exhaust plasm reactor 510 is discharged from the exhaust pipe plasma reactor 510, flows along the chamber exhaust pipe 107 and is collected in the powder collection trap 148. Also, the exhaust pipe plasma reactor 510 decomposes a NF₃ gas supplied by the exhaust pipe plasma source gas supplier 547 in a plasma reaction to generate excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction to generate excited fluorine atoms (F*) that are reactive species. The excited fluorine atoms (F*) generated in the exhaust pipe plasma reactor 510 and the remote plasma reactor 150 are supplied to the powder collection trap 148. In the powder collection trap 148, the TiO₂ powder reacts with the excited fluorine atoms (F*), is gasified and forms TiF₄. Thus, fluidity may be prevented from being reduced due to the TiO₂ powder accumulating in the exhaust equipment 105 including the vacuum pump 106.

Subsequently, the operation of the exhaust gas pretreatment equipment 509 when a ZrO₂ process using a process gas including a Zr-containing precursor is performed in the semiconductor process chamber 102, will be described as below. In the present embodiment, it will be described that (C₅H₅)Zr(N(CH₃)₂)₃ is used as the Zr-containing precursor. After the ZrO₂ process is performed in the semiconductor process chamber 102, an exhaust gas including unresponsive (C₅H₅)Zr(N(CH₃)₂)₃ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. (C₅H₅)Zr(N(CH₃)₂)₃ contained in the exhaust gas discharged from the semiconductor process chamber 102 reacts with oxygen in the exhaust pipe plasma reactor 510 by the operation of the exhaust pipe plasma reactor 510 to generate ZrO₂ that is stabilized powder. The ZrO₂ powder generated in the exhaust pipe plasma reactor 510 is discharged from the exhaust pipe plasma reactor 510, flows along the chamber exhaust pipe 107 and is collected in the powder collection trap 148. Also, the exhaust pipe plasma reactor 510 decomposes a NF₃ gas supplied by the exhaust pipe plasma source gas supplier 547 in a plasma reaction to generate excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction to generate excited fluorine atoms (F*) that are reactive species. The excited fluorine atoms (F*) generated in the exhaust pipe plasma reactor 510 and the remote plasma reactor 150 are supplied to the powder collection trap 148. In the powder collection trap 148, the ZrO₂ powder reacts with the excited fluorine atoms (F*), is gasified and forms ZrF₄. Thus, fluidity may be prevented from being reduced due to the ZrO₂ powder accumulating in the exhaust equipment 105 including the vacuum pump 106.

Subsequently, the operation of the exhaust gas pretreatment equipment 509 when an HfO₂ process using a process gas including an Hf-containing precursor is performed in the semiconductor process chamber 102, will be described as below. In the present embodiment, it will be described that (C₅H₅)Hf(N(CH₃)₂)₃ is used as the Hf-containing precursor. After the HfO₂ process is performed in the semiconductor process chamber 102, an exhaust gas including unresponsive (C₅H₅)Hf(N(CH₃)₂)₃ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. (C₅H₅)Hf(N(CH₃)₂)₃ contained in the exhaust gas discharged from the semiconductor process chamber 102 reacts with oxygen in the exhaust pipe plasma reactor 510 by the operation of the exhaust pipe plasma reactor 510 and forms HfO₂ that is stabilized powder. The HfO₂ powder generated in the exhaust pipe plasma reactor 510 is discharged from the exhaust pipe plasma reactor 510, flows along the chamber exhaust pipe 108 and is collected in the powder collection trap 148. Also, the exhaust pipe plasma reactor 510 decomposes a NF₃ gas supplied by the exhaust pipe plasma source gas supplier 547 in a plasma reaction to generate excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction to generate excited fluorine atoms (F*) that are reactive species. The excited fluorine atoms (F*) generated in the exhaust pipe plasma reactor 510 and the remote plasma reactor 150 are supplied to the powder collection trap 148. In the powder collection trap 148, the HfO₂ powder reacts with the excited fluorine atoms (F*), is gasified, and forms HfF₄. Thus, fluidity may be prevented from being reduced due to the HfO₂ powder accumulating in the exhaust equipment 105 including the vacuum pump 106.

Subsequently, the operation of the exhaust gas pretreatment equipment 509 when a Nb₂O₅ process using a process gas including a Nb-containing precursor is performed in the semiconductor process chamber 102, will be described as below. In the present embodiment, it will be described that (C₅H₅)Nb(N(CH₃)₂)₃ is used as the Nb-containing precursor. After the Nb₂O₅ process is performed in the semiconductor process chamber 102, an exhaust gas including unresponsive (C₅H₅)Nb(N(CH₃)₂)₃ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. (C₅H₅)Nb(N(CH₃)₂)₃ contained in the exhaust gas discharged from the semiconductor process chamber 102 reacts with oxygen in the exhaust pipe plasma reactor 510 by the operation of the exhaust pipe plasma reactor 510 and generates Nb₂O₅ that is stabilized powder. The Nb₂O₅ powder generated in the exhaust pipe plasma reactor 510 is discharged from the exhaust pipe plasma reactor 510, flows along the chamber exhaust pipe 107 and is collected in the powder collection trap 148. Also, the exhaust pipe plasma reactor 510 decomposes a NF₃ gas supplied by the exhaust pipe plasma source gas supplier 547 in a plasma reaction to generate excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction to generate excited fluorine atoms (F*) that are reactive species. The excited fluorine atoms (F*) generated in the exhaust pipe plasma reactor 510 and the remote plasma reactor 150 are supplied to the powder collection trap 148. In the powder collection trap 148, the Nb₂O₅ powder reacts with the excited fluorine atoms (F*), is gasified and forms NbF₅. Thus, fluidity may be prevented from being reduced due to the Nb₂05 powder accumulating in the exhaust equipment 105 including the vacuum pump 106.

Subsequently, the operation of the exhaust gas pretreatment equipment 509 when a Ta₂O₅ process using a process gas including a Ta-containing precursor is performed in the semiconductor process chamber 102, will be described as below. In the present embodiment, it will be described that Ta(OC₂H₅)₅ is used as the Ta-containing precursor. After the Ta₂O₅ process is performed in the semiconductor process chamber 102, the exhaust gas including unresponsive Ta(OC₂H₅)₅ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. Ta(OC₂H₅)₅ contained in the exhaust gas discharged from the semiconductor process chamber 102 reacts with oxygen in the exhaust pipe plasma reactor 510 by the operation of the exhaust pipe plasma reactor 510 and generates Ta₂O₅ that is stabilized powder. The Ta₂O₅ powder generated in the exhaust pipe plasma reactor 510 is discharged from the exhaust pipe plasma reactor 510, flows along the chamber exhaust pipe 107 and is collected in the powder collection trap 148. Also, the exhaust pipe plasma reactor 510 decomposes a NF₃ gas supplied by the exhaust pipe plasma source gas supplier 547 in a plasma reaction to generate excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction to generate excited fluorine atoms (F*) that are reactive species. The excited fluorine atoms (F*) generated in the exhaust pipe plasma reactor 510 and the remote plasma reactor 150 are supplied to the powder collection trap 148. In the powder collection trap 148, the Ta₂O₅ powder reacts with the excited fluorine atoms (F*), is gasified and forms TaF₅. Thus, fluidity may be prevented from being reduced due to the Ta₂O₅ powder accumulating in the exhaust equipment 105 including the vacuum pump 106.

### [Pretreatment Example 3]

In Pretreatment example 3, the exhaust pipe plasma reactor 510 is used to generate stabilized powder by oxidation, and reactive species generated by the remote plasma reactor 150 are used for powder gasification.

First, the operation of the exhaust gas pretreatment equipment 509 when a SiO₂ process using a process gas including TEOS(Si(OC₂H₅)₄) is performed in the semiconductor process chamber 102, will be described as below. After the SiO₂ process is performed in the semiconductor process chamber 102, an exhaust gas including unresponsive TEOS is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. TEOS contained in the exhaust gas discharged from the semiconductor process 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates SiO₂ that is stabilized powder. The SiO₂ powder generated in the exhaust pipe plasma reactor 110 is discharged from the exhaust pipe plasma reactor 110, flows along the chamber exhaust pipe 107 and is collected in the powder collection trap 148. Also, nitrogen trifluoride (NF₃) as a remote plasma source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated by the remote plasma reactor 150 are supplied to the powder collection trap 148. In the powder collection trap 148, as much SiO₂ powder is collected as possible and is gasified to react with the excited fluorine atoms (F*) to form SiF₄.

Subsequently, the operation of the exhaust gas pretreatment equipment 509 when a TiO₂ process using a process gas including Ti(OCH₂CH₃)₄ is performed in the semiconductor process chamber 102, will be described as below. After the TiO₂ process is performed in the semiconductor process chamber 102, the exhaust gas including unresponsive Ti(OCH₂CH₃)₄ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. Ti(OCH₂CH₃)₄ contained in the exhaust gas discharged from the semiconductor process chamber 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates TiO₂ that is stabilized powder. The TiO₂ powder generated in the exhaust pipe plasm reactor 510 is discharged from the exhaust pipe plasma reactor 510, flows along the chamber exhaust pipe 107 and is collected in the powder collection trap 148. Also, nitrogen trifluoride (NF₃) as a remote plasma source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated by the remote plasma reactor 150 are supplied to the powder collection trap 148. In the powder collection trap 148, as much TiO₂ powder is collected as possible and is gasified to react with the excited fluorine atoms (F*) to form TiF₄.

Subsequently, the operation of the exhaust gas pretreatment equipment 509 when a ZrO₂ process using a process gas including (C₅H₅)Zr(N(CH₃)₂)₃ is performed in the semiconductor process chamber 102, will be described as below. After the ZrO₂ process is performed in the semiconductor process chamber 102, the exhaust gas including unresponsive (C₅H₅)Zr(N(CH₃)₂)₃ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. (C₅H₅)Zr(N(CH₃)₂)₃ contained in the exhaust gas discharged from the semiconductor process chamber 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates ZrO₂ that is stabilized powder. The ZrO₂ powder generated in the exhaust pipe plasm reactor 510 is discharged from the exhaust pipe plasma reactor 510, flows along the chamber exhaust pipe 107 and is collected in the powder collection trap 148. Also, nitrogen trifluoride (NF₃) as a remote plasma source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated by the remote plasma reactor 150 are supplied to the powder collection trap 148. In the powder collection trap 148, as much ZrO₂ powder is collected as possible and is gasified to react with the excited fluorine atoms (F*) to form ZrF₄.

Subsequently, the operation of the exhaust gas pretreatment equipment 509 when a HfO₂ process using a process gas including (C₅H₅)Hf(N(CH₃)₂)₃ is performed in the semiconductor process chamber 102, will be described as below. After the HfO₂ process is performed in the semiconductor process chamber 102, the exhaust gas including unresponsive (C₅H₅)Hf(N(CH₃)₂)₃ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. (C₅H₅)Hf(N(CH₃)₂)₃ contained in the exhaust gas discharged from the semiconductor process chamber 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates HfO₂ that is stabilized powder. The HfO₂ powder generated in the exhaust pipe plasm reactor 510 is discharged from the exhaust pipe plasma reactor 510, flows along the chamber exhaust pipe 107 and is collected in the powder collection trap 148. Also, nitrogen trifluoride (NF₃) as a remote plasma source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated by the remote plasma reactor 150 are supplied to the powder collection trap 148. In the powder collection trap 148, as much HfO₂ powder is collected as possible and is gasified to react with the excited fluorine atoms (F*) to form HfF₄.

Subsequently, the operation of the exhaust gas pretreatment equipment 509 when a Nb₂O₅ process using a process gas including (C₅H₅)Nb(N(CH₃)₂)₃ is performed in the semiconductor process chamber 102, will be described as below. After the Nb₂O₅ process is performed in the semiconductor process chamber 102, the exhaust gas including unresponsive (C₅H₅)Nb(N(CH₃)₂)₃ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. (C₅H₅)Nb(N(CH₃)₂)₃ contained in the exhaust gas discharged from the semiconductor process chamber 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates Nb₂O₅ that is stabilized powder. The Nb₂O₅ powder generated in the exhaust pipe plasm reactor 510 is discharged from the exhaust pipe plasma reactor 510, flows along the chamber exhaust pipe 107 and is collected in the powder collection trap 148. Also, nitrogen trifluoride (NF₃) as a remote plasma source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated by the remote plasma reactor 150 are supplied to the powder collection trap 148. In the powder collection trap 148, as much Nb₂O₅ powder is collected as possible and is gasified to react with the excited fluorine atoms (F*) to form NbF₅.

Subsequently, the operation of the exhaust gas pretreatment equipment 509 when a Ta₂O₅ process using a process gas including Ta(OC₂H₅)₅ is performed in the semiconductor process chamber 102, will be described as below. After the Ta₂O₅ process is performed in the semiconductor process chamber 102, the exhaust gas including unresponsive Ta(OC₂H₅)₅ is discharged from the semiconductor process chamber 102 by the operation of the vacuum pump 106. While the exhaust gas is discharged from the semiconductor process chamber 102, the exhaust pipe plasma reactor 510 and the remote plasma reactor 150 operate. Ta(OC₂H₅)₅ contained in the exhaust gas discharged from the semiconductor process chamber 102 reacts with excited oxygen atoms (O*) generated by oxygen supplied by the exhaust pipe plasma source gas supplier 547 in the exhaust pipe plasma reactor 510 by the operation of the exhaust pipe plasma reactor 510 and generates Ta₂O₅ that is stabilized powder. The Ta₂O₅ powder generated in the exhaust pipe plasm reactor 510 is discharged from the exhaust pipe plasma reactor 510, flows along the chamber exhaust pipe 107 and is collected in the powder collection trap 148. Also, nitrogen trifluoride (NF₃) as a remote plasma source gas is supplied to the remote plasma reactor 150, and the remote plasma reactor 150 decomposes a NF₃ gas in a plasma reaction and generates excited fluorine atoms (F*) that are reactive species. The excited fluorine atoms (F*) generated by the remote plasma reactor 150 are supplied to the powder collection trap 148. In the powder collection trap 148, as much Ta₂O₅ powder is collected as possible and is gasified to react with the excited fluorine atoms (F*) to form TaF5.

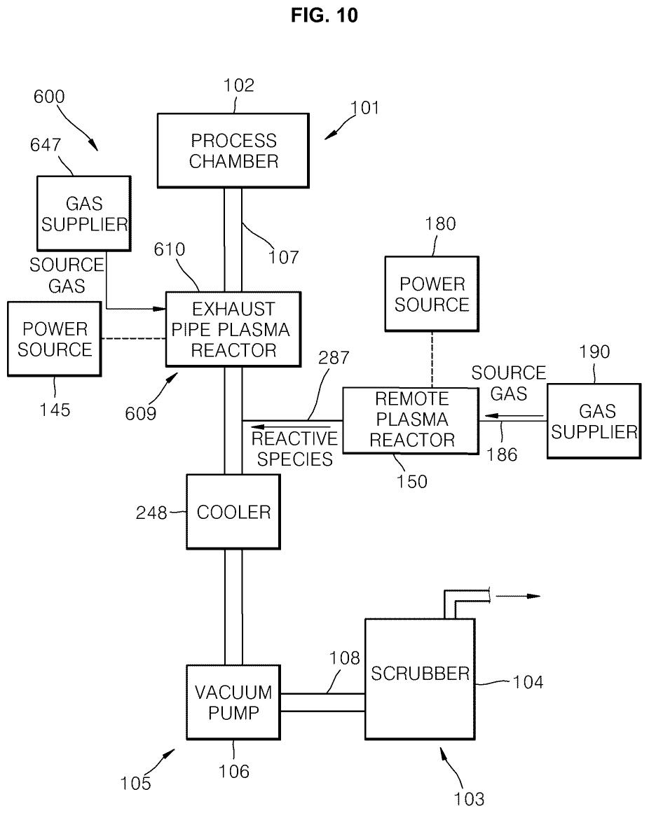

FIG. 10 is a block diagram illustrating a schematic configuration of a semiconductor manufacturing facility in which exhaust gas pretreatment equipment according to a sixth embodiment of the present invention is installed. Referring to FIG. 6, a semiconductor manufacturing facility 600 includes semiconductor manufacturing equipment 101 in which a semiconductor manufacturing process for manufacturing a semiconductor device is performed, gas purification equipment 103 for purifying gas discharged from the semiconductor manufacturing equipment 101, exhaust equipment 105 for discharging the gas from the semiconductor manufacturing equipment 101 to allow the gas to flow into the gas purification equipment 103, and exhaust gas pretreatment equipment 609 according to the sixth embodiment of the present invention that prevents reduction of the fluidity of the gas by pretreating the gas discharged from the semiconductor manufacturing equipment 101. The remaining configurations of the semiconductor manufacturing facility 600, except for the exhaust gas pretreatment equipment 609, are generally the same as the semiconductor manufacturing facility 200 shown in FIG. 6.

The exhaust gas pretreatment equipment 609 includes an exhaust pipe plasma reactor 610 that generates a plasma reaction with respect to an exhaust gas discharged from the semiconductor process chamber 102, an exhaust pipe reactor power source 145 that supplies power to the exhaust pipe plasma reactor 610, an exhaust pipe plasma source gas supplier 647 that supplies a source gas to the exhaust pipe plasma reactor 610, a cooler 248 installed on the chamber exhaust pipe 107, a remote reactor power source 180 that supplies power to the remote plasma reactor 150, and a remote plasma source gas supplier 190 that supplies gas to the remote plasma reactor 150.

The exhaust pipe plasma reactor 610 receives an exhaust pipe plasma source gas from the exhaust pipe plasma source gas supplier 647. The remaining configurations of the exhaust pipe plasma reactor 610, except for the configuration in which the exhaust pipe plasma reactor 610 receives the exhaust pipe plasma source gas from the exhaust pipe plasma source gas supplier 647, are generally the same as the configuration of the plasma reactor 110 described in the embodiment shown in FIG. 6 and thus, here, detailed descriptions thereof will be omitted.

The exhaust pipe reactor power source 145 is generally the same as the configuration of the exhaust pipe reactor power source 145 described in the embodiment shown in FIG. 6 and thus, here, detailed descriptions thereof will be omitted.

The exhaust pipe plasma source gas supplier 647 stores the exhaust pipe plasma source gas supplied to the exhaust pipe plasma reactor 510 and supplies the stored exhaust pipe plasma source gas to the exhaust pipe plasma reactor 610. In the present embodiment, it will be described that the exhaust pipe plasma source gas supplier 647 supplies nitrogen trifluoride (NF₃) or oxygen (O₂) to the exhaust pipe plasma reactor 610.

The cooler 248 is generally the same as the configuration of the cooler 248 described in the embodiment shown in FIG. 6 and thus, here, detailed descriptions thereof will be omitted.

The remote plasma rector 150 is generally the same as the configuration of the remote plasma reactor 150 described in the embodiment shown in FIG. 6 and thus, here, detailed descriptions thereof will be omitted.

The remote reactor power source 180 is generally the same as the configuration of the remote reactor power source 180 described in the embodiment shown in FIG. 6 and thus, here, detailed descriptions thereof will be omitted.

The remote plasma source gas supplier 190 is generally the same as the configuration of the remote plasma source gas supplier 190 described in the embodiment shown in FIG. 6 and thus, here, detailed descriptions thereof will be omitted.

Hereinafter, the operation of the exhaust gas pretreatment equipment 609 according to various processes performed in the semiconductor process chamber 102 will be described in detail.

First, the operation of the exhaust gas pretreatment equipment 609 when a SiO₂ process using a process gas including a Si-containing precursor is performed in the semiconductor process chamber 102, will be described as below. In the present embodiment, it will be described that TEOS is used as the Si-containing precursor. After the SiO₂ process is performed in the process chamber 102, an exhaust gas including unresponsive TEOS is discharged from the semiconductor process chamber 102 by the operation of the vacuum pump 106. While the exhaust gas is discharged from the semiconductor process chamber 102, the exhaust pipe plasma reactor 610 and the remote plasma reactor 150 operate. TEOS contained in the exhaust gas discharged from the semiconductor process chamber 102 reacts with oxygen in the exhaust pipe plasma reactor 610 by the operation of the exhaust pipe plasma reactor 610 and generates SiO₂ that is stabilized powder. The SiO₂ powder generated in the exhaust pipe plasma reactor 110 is discharged from the exhaust pipe plasma reactor 610 and flows along the chamber exhaust pipe 107. Also, the exhaust pipe plasma reactor 610 decomposes a NF₃ gas supplied by the exhaust pipe plasma source gas supplier 647 in a plasma reaction and generates excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction and generates excited fluorine atoms (F*) that are reactive species. The excited fluorine atoms (F*) generated by the remote plasma reactor 150 are supplied to a section between the exhaust pipe plasma reactor 610 and the cooler 248 in the chamber exhaust pipe 107. The SiO₂ powder generated by the exhaust pipe plasma reactor 610 reacts with excited fluorine atoms (F*) injected into the chamber exhaust pipe 107 and the excited fluorine atoms (F*) generated by the exhaust pipe plasma reactor 610 is gasified, and forms SiF₄. Thus, fluidity may be prevented from being reduced due to the SiO₂ powder accumulating in the exhaust equipment 105 including the vacuum pump 106.

Subsequently, the operation of the exhaust gas pretreatment equipment 609 when a TiO₂ process using a process gas including a Ti-containing precursor is performed in the semiconductor process chamber 102, will be described as below. In the present embodiment, it will be described that Ti(OCH₂CH₃)₄ is used as the Ti-containing precursor. After the TiO₂ process is performed in the semiconductor process chamber 102, the exhaust gas including unresponsive Ti(OCH₂CH₃)₄ is discharged from the semiconductor process chamber 102 by the operation of the vacuum pump 106. While the exhaust gas is discharged from the semiconductor process chamber 102, the exhaust pipe plasma reactor 610 and the remote plasma reactor 150 operate. Ti(OCH₂CH₃)₄ contained in the exhaust gas discharged from the semiconductor process chamber 102 reacts with oxygen in the exhaust pipe plasma reactor 610 by the operation of the exhaust pipe plasma reactor 610 and generates TiO₂ that is stabilized powder. The TiO₂ powder generated in the exhaust pipe plasma reactor 610 is discharged from the exhaust pipe plasma reactor 610 and flows along the chamber exhaust pipe 107. Also, the exhaust pipe plasma reactor 610 decomposes a NF₃ gas supplied by the exhaust pipe plasma source gas supplier 647 in a plasma reaction and generates excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction and generates excited fluorine atoms (F*) that are reactive species. The excited fluorine atoms (F*) generated by the remote plasma reactor 150 are supplied to the section between the exhaust pipe plasma reactor 610 and the cooler 248 in the chamber exhaust pipe 107. The TiO₂ powder generated by the exhaust pipe plasma reactor 610 reacts with excited fluorine atoms (F*) injected into the chamber exhaust pipe 107 and the excited fluorine atoms (F*) generated by the exhaust pipe plasma reactor 610 is gasified, and forms TiF₄. Thus, fluidity may be prevented from being reduced due to the TiO₂ powder accumulating in the exhaust equipment 105 including the vacuum pump 106.

Subsequently, the operation of the exhaust gas pretreatment equipment 609 when a ZrO₂ process using a process gas including a Zr-containing precursor is performed in the semiconductor process chamber 102, will be described as below. In the present embodiment, it will be described that (C₅H₅)Zr(N(CH₃)₂)₃ is used as the Zr-containing precursor. After the ZrO₂ process is performed in the semiconductor process chamber 102, an exhaust gas including unresponsive (C₅H₅)Zr(N(CH₃)₂)₃ is discharged from the semiconductor process chamber 102 by the operation of the vacuum pump 106. While the exhaust gas is discharged from the semiconductor process chamber 102, the exhaust pipe plasma reactor 610 and the remote plasma reactor 150 operate. (C₅H₅)Zr(N(CH₃)₂)₃ contained in the exhaust gas discharged from the semiconductor process chamber 102 with oxygen in the exhaust pipe plasma reactor 610 by the operation of the exhaust pipe plasma reactor 610 reacts and generates ZrO₂ that is stabilized powder. The ZrO₂ powder generated in the exhaust pipe plasma reactor 610 is discharged from the exhaust pipe plasma reactor 610 flows along the chamber exhaust pipe 107. Also, the exhaust pipe plasma reactor 610 decomposes a NF₃ gas supplied by the exhaust pipe plasma source gas supplier 647 in a plasma reaction and generates excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction and generates excited fluorine atoms (F*) that are reactive species. The excited fluorine atoms (F*) generated by the remote plasma reactor 150 are supplied to the section between the exhaust pipe plasma reactor 610 and the cooler 248 in the chamber exhaust pipe 107. The ZrO₂ powder generated by the exhaust pipe plasma reactor 610 reacts with excited fluorine atoms (F*) injected into the chamber exhaust pipe 107 and the excited fluorine atoms (F*) generated by the exhaust pipe plasma reactor 610 is gasified, and forms ZrF₄. Thus, fluidity may be prevented from being reduced due to the ZrO₂ powder accumulating in the exhaust equipment 105 including the vacuum pump 106.

Subsequently, the operation of the exhaust gas pretreatment equipment 609 when an HfO₂ process using a process gas including an Hf-containing precursor is performed in the semiconductor process chamber 102, will be described as below. In the present embodiment, it will be described that (C₅H₅)Hf(N(CH₃)₂)₃ is used as the Hf-containing precursor. After the HfO₂ process is performed in the semiconductor process chamber 102 by using the Hf-containing precursor, an exhaust gas including unresponsive (C₅H₅)Hf(N(CH₃)₂)₃ is discharged from the semiconductor process chamber 102 by the operation of the vacuum pump 106. While the exhaust gas is discharged from the semiconductor process chamber 102, the exhaust pipe plasma reactor 610 and the remote plasma reactor 150 operate. (C₅H₅)Hf(N(CH₃)₂)₃ contained in the exhaust gas discharged from the semiconductor process chamber 102 reacts with oxygen in the exhaust pipe plasma reactor 610 by the operation of the exhaust pipe plasma reactor 610 and generates HfO₂ that is stabilized powder. The HfO₂ powder generated in the exhaust pipe plasma reactor 610 is discharged from the exhaust pipe plasma reactor 610 and flows along the chamber exhaust pipe 107. Also, the exhaust pipe plasma reactor 610 decomposes a NF₃ gas supplied by the exhaust pipe plasma source gas supplier 647 in a plasma reaction and generates excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction and generates excited fluorine atoms (F*) that are reactive species. The excited fluorine atoms (F*) generated by the remote plasma reactor 150 are supplied to the section between the exhaust pipe plasma reactor 610 and the cooler 248 in the chamber exhaust pipe 107. The HfO₂ powder generated by the exhaust pipe plasma reactor 610 reacts with excited fluorine atoms (F*) injected into the chamber exhaust pipe 107 and the excited fluorine atoms (F*) generated by the exhaust pipe plasma reactor 610 is gasified, and forms HfF₄. Thus, fluidity may be prevented from being reduced due to the HfO₂ powder accumulating in the exhaust equipment 105 including the vacuum pump 106.

Subsequently, the operation of the exhaust gas pretreatment equipment 609 when a Nb₂O₅ process using a process gas including a Nb-containing precursor is performed in the semiconductor process chamber 102, will be described as below. In the present embodiment, it will be described that (C₅H₅)Nb(N(CH₃)₂)₃ is used as the Nb-containing precursor. After the Nb₂O₅ process is performed in the semiconductor process chamber 102, the exhaust gas including unresponsive (C₅H₅)Nb(N(CH₃)₂)₃ is discharged from the semiconductor process chamber 102 by the operation of the vacuum pump 106. While the exhaust gas is discharged from the semiconductor process chamber 102, the exhaust pipe plasma reactor 610 and the remote plasma reactor 150 operate. (C₅H₅)Nb(N(CH₃)₂)₃ contained in the exhaust gas discharged from the semiconductor process chamber 102 reacts with oxygen in the exhaust pipe plasma reactor 610 by the operation of the exhaust pipe plasma reactor 610 and generates Nb₂O₅ that is stabilized powder. The Nb₂O₅ powder generated in the exhaust pipe plasma reactor 610 is discharged from the exhaust pipe plasma reactor 610 and flows along the chamber exhaust pipe 107. Also, the exhaust pipe plasma reactor 610 decomposes a NF₃ gas supplied by the exhaust pipe plasma source gas supplier 647 in a plasma reaction and generates excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction and generates excited fluorine atoms (F*) that are reactive species. The excited fluorine atoms (F*) generated by the remote plasma reactor 150 are supplied to the section between the exhaust pipe plasma reactor 610 and the cooler 248 in the chamber exhaust pipe 107. The Nb₂O₅ powder generated by the exhaust pipe plasma reactor 610 reacts with excited fluorine atoms (F*) injected into the chamber exhaust pipe 107 and the excited fluorine atoms (F*) generated by the exhaust pipe plasma reactor 610 is gasified, and forms NbF₅. Thus, fluidity may be prevented from being reduced due to the Nb₂O₅ powder accumulating in the exhaust equipment 105 including the vacuum pump 106.

Subsequently, the operation of the exhaust gas pretreatment equipment 609 when a Ta₂O₅ process using a process gas including a Ta-containing precursor is performed in the semiconductor process chamber 102, will be described as below. In the present embodiment, it will be described that Ta(OC₂H₅)₅ is used as the Ta-containing precursor. After the Ta₂O₅ process is performed in the semiconductor process chamber 102, an exhaust gas including unresponsive Ta(OC₂H₅)₅ is discharged from the semiconductor process chamber 102 by the operation of the vacuum pump 106. While the exhaust gas is discharged from the semiconductor process chamber 102, the exhaust pipe plasma reactor 610 and the remote plasma reactor 150 operate. Ta(OC₂H₅)₅ contained in the exhaust gas discharged from the semiconductor process chamber 102 reacts with oxygen in the exhaust pipe plasma reactor 610 by the operation of the exhaust pipe plasma reactor 610 and generates Ta₂O₅ that is stabilized powder. The Ta₂O₅ powder generated in the exhaust pipe plasma reactor 610 is discharged from the exhaust pipe plasma reactor 610 and flows along the chamber exhaust pipe 107. Also, the exhaust pipe plasma reactor 610 decomposes a NF₃ gas supplied by the exhaust pipe plasma source gas supplier 647 in a plasma reaction and generates excited fluorine atoms (F*) that are reactive species. Nitrogen trifluoride (NF₃) as a source gas is supplied to the remote plasma reactor 150, and the remote plasma reactor 150 decomposes the NF₃ gas in a plasma reaction and generates excited fluorine atoms (F*) that are reactive species. The excited fluorine atoms (F*) generated by the remote plasma reactor 150 are supplied to the section between the exhaust pipe plasma reactor 610 and the cooler 248 in the chamber exhaust pipe 107. The Ta₂O₅ powder generated by the exhaust pipe plasma reactor 610 reacts with excited fluorine atoms (F*) injected into the chamber exhaust pipe 107 and the excited fluorine atoms (F*) generated by the exhaust pipe plasma reactor 610 is gasified, and forms TaF₅. Thus, fluidity may be prevented from being reduced due to the Ta₂O₅ powder accumulating in the exhaust equipment 105 including the vacuum pump 106.

Subsequently, the operation of the exhaust gas pretreatment equipment 609 when an ACL process is performed in the semiconductor process chamber 102, will be described as below. After the ACL process is performed in the semiconductor process chamber 102, the exhaust gas including hydrogenated amorphous carbon (a-C:H) is discharged from the semiconductor process chamber 102 by the operation of the vacuum pump 106. While the exhaust gas is discharged from the semiconductor process chamber 102, the exhaust pipe plasma reactor 610 and the remote plasma reactor 150 operate. a-C:H contained in the exhaust gas discharged from the semiconductor process chamber 102 is decompose into the excited carbon atoms (C*) and the excited hydrogen atoms (H*) by a plasma reaction in the exhaust pipe plasma reactor 610. The excited carbon atoms (C*) and the excited hydrogen atoms (H*) generated in the exhaust pipe plasma reactor 110 is discharged from the exhaust pipe plasma reactor 110 and flows along the chamber exhaust pipe 107. Also, the exhaust pipe plasma reactor 610 decomposes an O₂ gas supplied by the exhaust pipe plasma source gas supplier 647 in a plasma reaction and generates excited oxygen atoms (O*) that are reactive species. Oxygen (O₂) as a source gas is supplied to the remote plasma reactor 150, and the remote plasma reactor 150 decomposes the O₂ gas in a plasma reaction and generates excited oxygen atoms (O*) that are reactive species. The excited oxygen atoms (O*) generated by the remote plasma reactor 150 are supplied to the section between the exhaust pipe plasma reactor 610 and the cooler 248 in the chamber exhaust pipe 107. A substitution (oxidation) reaction occurs between the excited caron atoms (C*) generated by the exhaust pipe plasma reactor 610, the excited hydrogen atoms (H*), and the excited oxygen (O*) injected into the chamber exhaust pipe 107 so that carbon dioxide (CO₂) gas, carbon oxide (CO) gas and water vapor (H₂O) are generated. Thus, fluidity may be prevented from being reduced due to a-C:H accumulating in the exhaust equipment 105 including the vacuum pump 106.

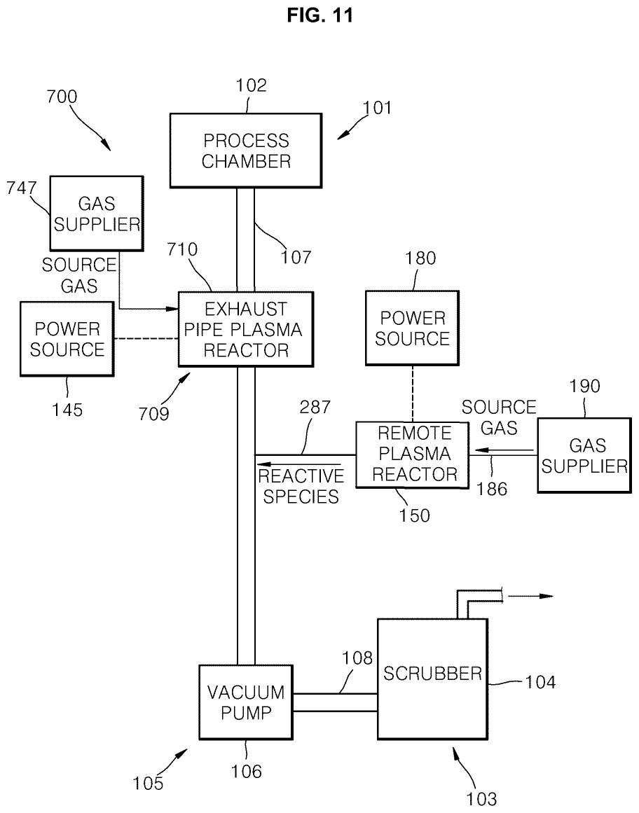

FIG. 11 is a block diagram illustrating a schematic configuration of a semiconductor manufacturing facility in which exhaust gas pretreatment equipment according to a seventh embodiment of the present invention is installed. Referring to FIG. 11, a semiconductor manufacturing facility 700 includes semiconductor manufacturing equipment 101 in which a semiconductor manufacturing process for manufacturing a semiconductor device is performed, gas purification equipment 103 for purifying gas discharged from the semiconductor manufacturing equipment 101, exhaust equipment 105 for discharging the gas from the semiconductor manufacturing equipment 101 to allow the gas to flow into the gas purification equipment 103, and exhaust gas pretreatment equipment 709 according to the seventh embodiment of the present invention that prevents reduction of the fluidity of the gas by pretreating the gas discharged from the semiconductor manufacturing equipment 101. The remaining configurations of the semiconductor manufacturing facility 700, except for the exhaust gas pretreatment equipment 709, are generally the same as the semiconductor manufacturing facility 300 shown in FIG. 7.

The exhaust gas pretreatment equipment 709 includes an exhaust pipe plasma reactor 710 that generates a plasma reaction with respect to an exhaust gas discharged from the semiconductor process chamber 102, an exhaust pipe reactor power source 145 that supplies power to the exhaust pipe plasma reactor 710, an exhaust pipe plasma source gas supplier 747 that supplies a source gas to the exhaust pipe plasma reactor 710, a remote plasma reactor 150 that generates reactive species to be supplied to the chamber exhaust pipe 107 by using plasma, a remote reactor power source 180 that supplies power to the remote plasma reactor 150, and a remote plasma source gas supplier 190 that supplies gas to the remote plasma reactor 150. The exhaust gas pretreatment equipment 709 is the configuration in which the cooler 248 is excluded from the exhaust gas pretreatment equipment 609 shown in FIG. 10, and does not require cooling compared to the exhaust gas pretreatment equipment 609 shown in FIG. 10 so that energy consumption efficiency in the operation of the exhaust gas pretreatment equipment 709 is improved. The operation of the exhaust gas pretreatment equipment 709 is generally the same as the operation of the exhaust gas pretreatment equipment 609 described in the embodiment of FIG. 10.

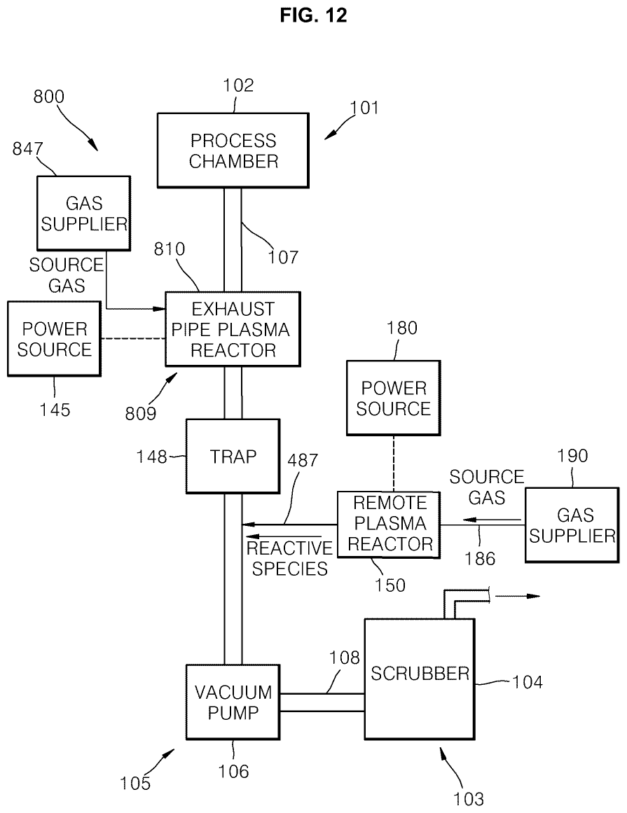

FIG. 12 is a block diagram illustrating a schematic configuration of a semiconductor manufacturing facility in which exhaust gas pretreatment equipment according to an eighth embodiment of the present invention is installed. Referring to FIG. 12, a semiconductor manufacturing facility 800 includes semiconductor manufacturing equipment 101 in which a semiconductor manufacturing process for manufacturing a semiconductor device is performed, gas purification equipment 103 for purifying gas discharged from the semiconductor manufacturing equipment 101, exhaust equipment 105 for discharging the gas from the semiconductor manufacturing equipment 101 to allow the gas to flow into the gas purification equipment 103, and exhaust gas pretreatment equipment 809 according to the seventh embodiment of the present invention that prevents reduction of the fluidity of the gas by pretreating the gas discharged from the semiconductor manufacturing equipment 101. The remaining configurations of the semiconductor manufacturing facility 800, except for the exhaust gas pretreatment equipment 809, are generally the same as the semiconductor manufacturing facility 400 shown in FIG. 8 and thus, here, only the exhaust gas pretreatment equipment 809 will be described.

The exhaust gas pretreatment equipment 809 includes an exhaust pipe plasma reactor 810 that generates a plasma reaction with respect to an exhaust gas discharged from the semiconductor process chamber 102, an exhaust pipe reactor power source 145 that supplies power to the exhaust pipe plasma reactor 810, an exhaust pipe plasma source gas supplier 647 that supplies a source gas to the exhaust pipe plasma reactor 810, a powder collection trap 148 that is installed on the chamber exhaust pipe 107 and collects powder, a remote plasma reactor 150 that generates reactive species to be supplied to the chamber exhaust pipe 107 by using plasma, a remote reactor power source 180 that supplies power to the remote plasma reactor 150, a remote plasma source gas supplier 190 that supplies gas to the remote plasma reactor 150, and a remote plasma source gas supplier 190 that supplies gas to the remote plasma reactor 150.

The exhaust pipe plasma reactor 810 receives an exhaust pipe plasma source gas from the exhaust pipe plasma source gas supplier 847. The remaining configurations of the exhaust pipe plasma reactor 810, except for the configuration in which the exhaust pipe plasma reactor 810 receives an exhaust pipe plasma source gas from the exhaust pipe plasma source gas supplier 847, is generally the same as the configuration of the exhaust pipe plasma reactor 410 described in the embodiment shown in FIG. 8 and thus, here, detailed descriptions thereof will be omitted.

The exhaust pipe reactor power source 145 is generally the same as the configuration of the exhaust pipe reactor power source 145 described in the embodiment shown in FIG. 1 and thus, here, detailed descriptions thereof will be omitted.

The powder collection trap 148 is generally the same as the configuration of the powder collection trap 148 described in the embodiment shown in FIG. 1 and thus, here, detailed descriptions thereof will be omitted.

The remote plasma reactor 150 is generally the same as the configuration of the remote plasma reactor 150 described in the embodiment shown in FIG. 1 and thus, here, detailed descriptions thereof will be omitted. A gas outlet (163 of FIG. 4) of the remote plasma reactor 150 communicates with the chamber exhaust pipe 107 through a discharge pipe 487. The discharge pipe 487 is directly connected to a section between the powder collection trap 148 and the vacuum pump 106 in the chamber exhaust pipe 107. Thus, reactive species generated in the remote plasma reactor 150 is charged through the outlet 164 and then flows along the discharge pipe 487 and is directly introduced into the chamber exhaust pipe 107 in the section between the power collection trap 148 and the vacuum pump 106.

The remote reactor power source 180 is generally the same as the configuration of the remote reactor power source 180 described in the embodiment shown in FIG. 1 and thus, here, detailed descriptions thereof will be omitted.

The remote plasma source gas supplier 190 is generally the same as the configuration of the remote plasma source gas supplier 190 described in the embodiment shown in FIG. 1 and thus, here, detailed descriptions thereof will be omitted.

Hereinafter, the operation of the exhaust gas pretreatment equipment 809 according to various processes performed in the semiconductor process chamber 102 will be described in detail.

First, the operation of the exhaust gas pretreatment equipment 809 when a SiO₂ process using a process gas including TEOS(Si(OC₂H₅)₄) is performed in the semiconductor process chamber 102, will be described as below. After the SiO₂ process is performed in the semiconductor process chamber 102, an exhaust gas including unresponsive TEOS is discharged from the semiconductor process chamber 102 by the operation of the vacuum pump 106. While the exhaust gas is discharged from the semiconductor process chamber 102, the exhaust pipe plasma reactor 810 and the remote plasma reactor 150 operate. TEOS contained in the exhaust gas discharged from the semiconductor process 102 reacts with excited oxygen atoms (O*) generated by oxygen supplied by the exhaust pipe plasma source gas supplier 847 in the exhaust pipe plasma reactor 810 by the operation of the exhaust pipe plasma reactor 810 and generates SiO₂ that is stabilized powder. The SiO₂ powder generated in the exhaust pipe plasma reactor 810 is discharged from the exhaust pipe plasma reactor 110, flows along the chamber exhaust pipe 107 and is collected in the powder collection trap 148, and uncollected SiO₂ powder that is not collected in the powder collection trap 148 passes through the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to a section between the powder collection trap 148 and the vacuum pump 106 in the chamber exhaust pipe 107. The uncollected SiO₂ powder passing through the powder collection trap 148 reacts with the excited fluorine atoms (F*) injected into the chamber exhaust pipe 107, is gasified and forms SiF₄ . Thus, fluidity may be prevented from being reduced due to the uncollected SiO₂ powder accumulating in the exhaust equipment 105 including the vacuum pump 106.

Subsequently, the operation of the exhaust gas pretreatment equipment 809 when a TiO₂ process using a process gas including Ti(OCH₂CH₃)₄ is performed in the semiconductor process chamber 102, will be described as below. After the TiO₂ process is performed in the semiconductor process chamber 102, an exhaust gas including unresponsive Ti(OCH₂CH₃)₄ is discharged from the semiconductor process chamber 102 by the operation of the vacuum pump 106. While the exhaust gas is discharged from the semiconductor process chamber 102, the exhaust pipe plasma reactor 810 and the remote plasma reactor 150 operate. Ti(OCH₂CH₃)₄ contained in the exhaust gas discharged from the semiconductor process chamber 102 reacts with excited oxygen atoms (O*) generated by oxygen supplied by the exhaust pipe plasma source gas supplier 847 in the exhaust pipe plasma reactor 810 by the operation of the exhaust pipe plasma reactor 810 and generates TiO₂ that is stabilized powder. The TiO₂ powder generated in the exhaust pipe plasma reactor 110 is discharged from the exhaust pipe plasma reactor 810, flows along the chamber exhaust pipe 107 and is collected in the powder collection trap 148, and the uncollected TiO₂ powder that is not collected in the powder collection trap 148 passes through the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to a section between the powder collection trap 148 and the vacuum pump 106 in the chamber exhaust pipe 107. The uncollected TiO₂ powder passing through the powder collection trap 148 reacts with the excited fluorine atoms (F*) injected into the chamber exhaust pipe 107, is gasified and forms TiF₄. Thus, fluidity may be prevented from being reduced due to the uncollected TiO₂ powder accumulating in the exhaust equipment 105 including the vacuum pump 106.

Subsequently, the operation of the exhaust gas pretreatment equipment 809 when a ZrO₂ process using a process gas including (C₅H₅)Zr(N(CH₃)₂)₃ is performed in the semiconductor process chamber 102, will be described as below. After the ZrO₂ process is performed in the semiconductor process chamber 102, an exhaust gas including unresponsive (C₅H₅)Zr(N(CH₃)₂)₃ is discharged from the semiconductor process chamber 102 by the operation of the vacuum pump 106. While the exhaust gas is discharged from the semiconductor process chamber 102, the exhaust pipe plasma reactor 810 and the remote plasma reactor 150 operate. (C₅H₅)Zr(N(CH₃)₂)₃ contained in the exhaust gas discharged from the semiconductor process chamber 102 reacts with excited oxygen atoms (O*) generated by oxygen supplied by the exhaust pipe plasma source gas supplier 847 in the exhaust pipe plasma reactor 810 by the operation of the exhaust pipe plasma reactor 810 to generate ZrO₂ that is stabilized powder. The ZrO₂ powder generated in the exhaust pipe plasma reactor 810 is discharged from the exhaust pipe plasma reactor 810, flows along the chamber exhaust pipe 107 and is collected in the powder collection trap 148, and uncollected ZrO₂ powder that is not collected in the powder collection trap 148 passes through the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to the section between the powder collection trap 148 and the vacuum pump 106 in the chamber exhaust pipe 107. The uncollected ZrO₂ powder passing through the powder collection trap 148 reacts with the excited fluorine atoms (F*) injected into the chamber exhaust pipe 107, is gasified and forms ZrF₄. Thus, fluidity may be prevented from being reduced due to the uncollected ZrO₂ powder accumulating in the exhaust equipment 105 including the vacuum pump 106.

Subsequently, the operation of the exhaust gas pretreatment equipment 809 when an HfO₂ process using a process gas including (C₅H₅)Hf(N(CH₃)₂)₃ is performed in the semiconductor process chamber 102, will be described as below. After the HfO₂ process is performed in the semiconductor process chamber 102, an exhaust gas including unresponsive (C₅H₅)Hf(N(CH₃)₂)₃ is discharged from the semiconductor process chamber 102 by the operation of the vacuum pump 106. While the exhaust gas is discharged from the semiconductor process chamber 102, the exhaust pipe plasma reactor 810 and the remote plasma reactor 150 operate. (C₅H₅)Hf(N(CH₃)₂)₃ contained in the exhaust gas discharged from the semiconductor process chamber 102 reacts with excited oxygen atoms (O*) generated by oxygen supplied by the exhaust pipe plasma source gas supplier 847 in the exhaust pipe plasma reactor 810 by the operation of the exhaust pipe plasma reactor 810 and forms HfO₂ that is stabilized powder. The HfO₂ powder generated in the exhaust pipe plasma reactor 810 is discharged from the exhaust pipe plasma reactor 810, flows along the chamber exhaust pipe 107 and is collected in the powder collection trap 148, and the uncollected HfO₂ powder that is not collected in the powder collection trap 148 passes through the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to the section between the powder collection trap 148 and vacuum pump 106 in the chamber exhaust pipe 107. The uncollected HfO₂ powder passing through the powder collection trap 148 reacts with the excited fluorine atoms (F*) injected into the chamber exhaust pipe 107, is gasified, and forms HfF₄. Thus, fluidity may be prevented from being reduced due to the HfO₂ powder accumulating in the exhaust equipment 105 including the vacuum pump 106.

Subsequently, the operation of the exhaust gas pretreatment equipment 809 when a Nb₂O₅ process using a process gas including (C₅H₅)Nb(N(CH₃)₂)₃ is performed in the semiconductor process chamber 102, will be described as below. After the Nb₂O₅ process is performed in the semiconductor process chamber 102, an exhaust gas including unresponsive (C₅H₅)Nb(N(CH₃)₂)₃ is discharged from the semiconductor process chamber 102 by the operation of the vacuum pump 106. While the exhaust gas is discharged from the semiconductor process chamber 102, the exhaust pipe plasma reactor 810 and the remote plasma reactor 150 operate. (C₅H₅)Nb(N(CH₃)₂)₃ contained in the exhaust gas discharged from the semiconductor process chamber 102 reacts with excited oxygen atoms (O*) generated by oxygen supplied by the exhaust pipe plasma source gas supplier 847 in the exhaust pipe plasma reactor 810 by the operation of the exhaust pipe plasma reactor 810 and generates Nb₂O₅ that is stabilized powder. The Nb₂O₅ powder generated in the exhaust pipe plasma reactor 810 is discharged from the exhaust pipe plasma reactor 810, flows along the chamber exhaust pipe 107 and is collected in the powder collection trap 148, and the uncollected Nb₂O₅ powder that is not collected in the powder collection trap 148 passes through the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to the section between the powder collection trap 148 and the vacuum pump 106 in the chamber exhaust pipe 107. The uncollected Nb₂O₅ powder passing through the powder collection trap 148 reacts with the excited fluorine atoms (F*) injected into the chamber exhaust pipe 107, is gasified and forms NbF₅. Thus, fluidity may be prevented from being reduced due to the Nb₂O₅ powder accumulating in the exhaust equipment 105 including the vacuum pump 106.

Subsequently, the operation of the exhaust gas pretreatment equipment 809 when a Ta₂O₅ process using a process gas including Ta(OC₂H₅)₅ is performed in the semiconductor process chamber 102, will be described as below. After the Ta₂O₅ process is performed in the semiconductor process chamber 102, the exhaust gas including unresponsive Ta(OC₂H₅)₅ is discharged from the semiconductor process chamber 102 by the operation of the vacuum pump 106. While the exhaust gas is discharged from the semiconductor process chamber 102, the exhaust pipe plasma reactor 110 and the remote plasma reactor 150 operate. Ta(OC₂H₅)₅ contained in the exhaust gas discharged from the semiconductor process chamber 102 reacts with excited oxygen atoms (O*) generated by oxygen supplied by the exhaust pipe plasma source gas supplier 847 in the exhaust pipe plasma reactor 810 by the operation of the exhaust pipe plasma reactor 810 and generates Ta₂O₅ that is stabilized powder. The Ta₂O₅ powder generated in the exhaust pipe plasma reactor 810 is discharged from the exhaust pipe plasma reactor 810, flows along the chamber exhaust pipe 107 and is collected in the powder collection trap 148, and the uncollected Ta₂O₅ powder that is not collected in the powder collection trap 148 passes through the powder collection trap 148 and flows along the chamber exhaust pipe 107. Nitrogen trifluoride (NF₃) as a source gas is supplied to the remote plasma reactor 150, and the remote plasma reactor 150 decomposes a NF₃ gas in a plasma reaction to generate excited fluorine atoms (F*) that are reactive species. The excited fluorine atoms (F*) generated in the remote plasma reactor 150 are supplied to the section between the powder collection trap 148 and the vacuum pump 106 in the chamber exhaust pipe 107. The uncollected Ta₂O₅ powder passing through the power collection trap 148 reacts with the excited fluorine atoms (F*) injected into the chamber exhaust pipe 108, is gasified and forms TaF5. Thus, fluidity may be prevented from being reduced due to the Ta₂O₅ powder accumulating in the exhaust equipment 105 including the vacuum pump 106.

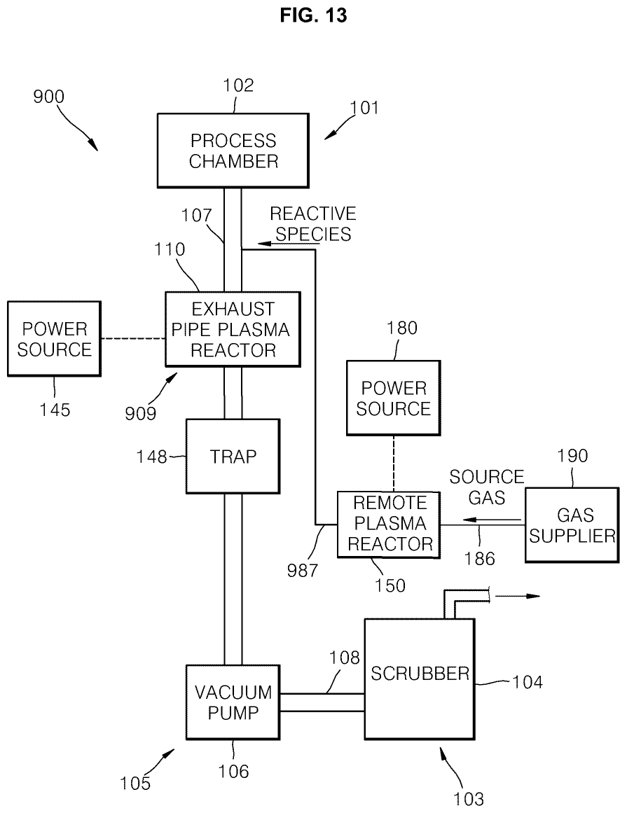

FIG. 13 is a block diagram illustrating a schematic configuration of a semiconductor manufacturing facility in which exhaust gas pretreatment equipment according to a ninth embodiment of the present invention is installed. Referring to FIG. 13, a semiconductor manufacturing facility 900 includes semiconductor manufacturing equipment 101 in which a semiconductor manufacturing process for manufacturing a semiconductor device is performed, gas purification equipment 103 for purifying gas discharged from the semiconductor manufacturing equipment 101, exhaust equipment 105 for discharging the gas from the semiconductor manufacturing equipment 101 to allow the gas to flow into the gas purification equipment 103, and exhaust gas pretreatment equipment 909 according to the ninth embodiment of the present invention that prevents reduction of the fluidity of the gas by pretreating the gas discharged from the semiconductor manufacturing equipment 101. The remaining configurations of the semiconductor manufacturing facility 900, except for the exhaust gas pretreatment equipment 909, are generally the same as the semiconductor manufacturing facility 100 shown in FIG. 1.

The exhaust gas pretreatment equipment 909 includes an exhaust pipe plasma reactor 110 that generates a plasma reaction with respect to gas discharged from the semiconductor process chamber 102, an exhaust pipe reactor power source 145 that supplies power to the exhaust pipe plasma reactor 110, a powder collection trap 148 that is installed on the chamber exhaust pipe 107 and collects powder, a remote plasma reactor 150 that generates a responsive species to be supplied to an upstream of the exhaust pipe plasma reactor 110, a remote reactor power source 180 that supplies power to the remote plasma reactor 150, and a remote plasma source gas supplier 190 that supplies gas to the remote plasma reactor 150. The present embodiment is the same as the embodiment shown in FIG. 1, except that the reactive species generated in the remote plasma reactor 150 is supplied to the upstream of the exhaust pipe plasma reactor 110 through the discharge pipe 987. In the present embodiment, it will be described that the reactive species generated in the remote plasma reactor 150 are supplied to the chamber exhaust pipe 107 through the discharge pipe 987.

A reaction in which stabilized powder is formed in the exhaust gas by the operation of the exhaust pipe plasma reactor 110 and the stabilized power is formed according to types of processes, is described as the embodiment of FIG. 1.

The powder reacts with the reactive species and is gasified by the operation of the remote plasma reactor 150. The reaction in which the powder is gasified according to the types of processes, is described as the embodiment of FIG. 1. When the remote plasma reactor 150 operates in the state in which the operation of the semiconductor process chamber 102 stops after the process by the semiconductor process chamber 102 is completed, the effect of internal cleaning (removal of deposition of by-products) of the exhaust pipe plasma reactor 110 may be expected.

Thus, changes in the internal environment (impedance) due to deposition of by-products inside the exhaust pipe plasma reactor 110 as the process progresses are prevented, and the impact on the pressure increase in the equipment is reduced, and the number of PM progresses in the exhaust pipe plasma reactor 110 is also reduced, so that the MTBF of the exhaust pipe plasma reactor 110 can be increased.

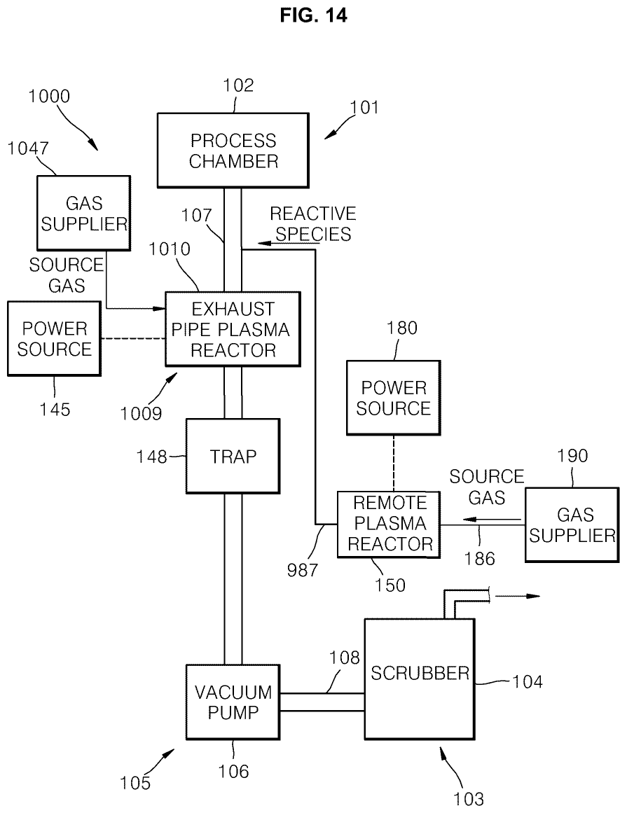

FIG. 14 is a block diagram illustrating a schematic configuration of a semiconductor manufacturing facility in which exhaust gas pretreatment equipment according to a tenth embodiment of the present invention is installed. Referring to FIG. 14, a semiconductor manufacturing facility 1000 includes semiconductor manufacturing equipment 101 in which a semiconductor manufacturing process for manufacturing a semiconductor device is performed, gas purification equipment 103 for purifying gas discharged from the semiconductor manufacturing equipment 101, exhaust equipment 105 for discharging the gas from the semiconductor manufacturing equipment 101 to allow the gas to flow into the gas purification equipment 103, and exhaust gas pretreatment equipment 1009 according to the tenth embodiment of the present invention that prevents reduction of the fluidity of the gas by pretreating the gas discharged from the semiconductor manufacturing equipment 101. The remaining configurations of the semiconductor manufacturing facility 1000, except for the exhaust gas pretreatment equipment 1009, are generally the same as the semiconductor manufacturing facility 900 shown in FIG. 13.

The exhaust gas pretreatment equipment 1009 includes an exhaust pipe plasma reactor 1010 that generates a plasma reaction with respect to gas discharged from the semiconductor process chamber 102, an exhaust pipe reactor power source 145 that supplies power to the exhaust pipe plasma reactor 110, an exhaust pipe plasma source gas supplier 1047 that supplies a source gas to the exhaust pipe plasma reactor 1010, a powder collection trap 148 that is installed on the chamber exhaust pipe 107 and collects powder, a remote plasma reactor 150 that generates a responsive species to be supplied to an upstream of the exhaust pipe plasma reactor 110, a remote reactor power source 180 that supplies power to the remote plasma reactor 150, and a remote plasma source gas supplier 190 that supplies gas to the remote plasma reactor 150. The reactive species generated in the remote plasma reactor 150 are supplied to the upstream of the exhaust pipe plasma reactor 110 through the discharge pipe 987.

The present embodiment is the same as the embodiment shown in FIG. 13, except for the configuration in which the exhaust pipe plasma reactor 1010 receives an exhaust gas plasma source gas from the exhaust pipe plasma source gas supplier 1047 and thus, here, detailed descriptions thereof will be omitted. The remaining configurations except for the configuration in which the exhaust pipe plasma reactor 1010 receives an exhaust gas plasma source gas from the exhaust pipe plasma source gas supplier 1047, is generally the same as the configuration of the exhaust pipe plasma reactor 110 described in the embodiment shown in FIG. 13 and thus, here, detailed descriptions thereof will be omitted. The exhaust pipe plasma source gas supplier 1047 supplies nitrogen trifluoride NF₃ or oxygen (O₂) to the exhaust pipe plasma reactor 1010. Thus, excited fluorine atoms (F*) or excited oxygen atoms (O*) that are reactive species are generated in the exhaust pipe plasma reactor 1010.

While the present invention has been particularly shown and described with reference to exemplary embodiments thereof, it will be understood by those of ordinary skill in the art that various changes in form and details may be made therein without departing from the spirit and scope of the present invention as defined by the following claims.

1. Exhaust gas pretreatment equipment for semiconductor manufacturing facilities, the exhaust gas pretreatment equipment for pretreating an exhaust gas discharged from a semiconductor process chamber in which a semiconductor manufacturing process using a process gas is performed, by using a vacuum pump through a chamber exhaust pipe connecting the semiconductor process chamber to the vacuum pump, the exhaust gas pretreatment equipment comprising:
an exhaust pipe plasma reactor installed on the chamber exhaust pipe and generating plasma in the exhaust gas to remove ingredients to be removed contained in the exhaust gas; and
a remote plasma reactor generating plasma to decompose a remote plasma source gas and generating a remote plasma gas including reactive species,
wherein the remote plasma gas is supplied to a section between the exhaust pipe plasma reactor and the vacuum pump in a flow line of the exhaust gas.

2. The exhaust gas pretreatment equipment of claim 1, further comprising a powder collection trap installed downstream of the exhaust pipe plasma reactor on the chamber exhaust pipe to collect powder contained in the exhaust gas,
wherein the remote plasma gas is supplied to the powder collection trap so that the ingredients to be removed that are not removed from the exhaust pipe plasma reactor are additionally removed.

3-9. (canceled)

10. The exhaust gas pretreatment equipment of claim 1, further comprising a cooler installed downstream of the exhaust pipe plasma reactor on the chamber exhaust pipe to reduce temperature of the exhaust gas, and the remote plasma gas is supplied to a section between the exhaust pipe plasma reactor and the cooler in the chamber exhaust so that the ingredients to be removed that are not removed from the exhaust plasma reactor are additionally removed.

11. The exhaust gas pretreatment equipment of claim 1, wherein the remote plasma gas is supplied to a section between the exhaust pipe plasma reactor and the vacuum pump in the chamber exhaust pipe so that the ingredients to be removed that are not removed from the exhaust plasma reactor are additionally removed.

12-18. (canceled)

19. The exhaust gas pretreatment equipment of claim 1, further comprising a powder collection trap installed downstream of the exhaust pipe plasma reactor on the chamber exhaust pipe to collect powder contained in the exhaust gas,
wherein the remote plasma gas is supplied to a section between the powder collection trap and the vacuum pump so that the ingredients to be removed that are not removed from the exhaust pipe plasma reactor are additionally removed.

20. The exhaust gas pretreatment equipment of claim 19, wherein the exhaust gas comprises a silicon (Si)-containing precursor and oxygen, and in the exhaust pipe plasma reactor, the Si-containing precursor reacts with the oxygen to form a SiO₂ powder, and the remote plasma source gas is nitrogen trifluoride (NF₃), and the reactive species are excited fluorine atoms (F*), and the SiO₂ powder reacts with the excited fluorine atoms (F*) to form a SiF₄ gas.

21. The exhaust gas pretreatment equipment of claim 19, wherein the exhaust gas comprises a titanium (Ti)-containing precursor and oxygen, and in the exhaust pipe plasma reactor, the Ti-containing precursor reacts with the oxygen to form a TiO₂ powder, and the remote plasma source gas is nitrogen trifluoride (NF₃), and the reactive species are excited fluorine atoms (F*), and the TiO₂ powder reacts with the excited fluorine atoms (F*) to form a TiF₄ gas.

22. The exhaust gas pretreatment equipment of claim 19, wherein the exhaust gas comprises a zirconium (Zr)-containing precursor and oxygen, and in the exhaust pipe plasma reactor, the Zr-containing precursor reacts with the oxygen to form a ZrO₂ powder, and the remote plasma source gas is nitrogen trifluoride (NF₃), and the reactive species are excited fluorine atoms (F*), and the ZrO₂ powder reacts with the excited fluorine atoms (F*) to form a ZrF₄ gas.

23. The exhaust gas pretreatment equipment of claim 19, wherein the exhaust gas comprises a hafnium (Hf)-containing precursor and oxygen, and in the exhaust pipe plasma reactor, the Hf-containing precursor reacts with the oxygen to form an HfO₂ powder, and the remote plasma source gas is nitrogen trifluoride (NF₃), and the reactive species are excited fluorine atoms (F*), and the HfO₂ powder reacts with the excited fluorine atoms (F*) to form an HfF₄ gas.

24. The exhaust gas pretreatment equipment of claim 19, wherein the exhaust gas comprises a niobium (Nb)-containing precursor and oxygen, and in the exhaust pipe plasma reactor, the Nb-containing precursor reacts with the oxygen to form a Nb₂O₅ powder, and the remote plasma source gas is nitrogen trifluoride (NF₃), and the reactive species are excited fluorine atoms (F*), and the Nb₂O₅ powder reacts with the excited fluorine atoms (F*) to form a NbF₅ gas.

25. The exhaust gas pretreatment equipment of claim 19, wherein the exhaust gas comprises a tantalum (Ta)-containing precursor and oxygen, and in the exhaust pipe plasma reactor, the Ta-containing precursor reacts with the oxygen to form a Ta₂O₅ powder, and the remote plasma source gas is nitrogen trifluoride (NF₃), and the reactive species are excited fluorine atoms (F*), and the Ta₂O₅ powder reacts with the excited fluorine atoms (F*) to form a TaF₅ gas.

26. The exhaust gas pretreatment equipment of claim 19, wherein the exhaust gas comprises hydrogenated amorphous carbon (a-C:H), and the a-C:H is decomposed into excited carbon atoms (C*) and excited hydrogen atoms (H*) in the exhaust pipe plasma reactor in the exhaust pipe plasma reactor, and the remote plasma source gas is oxygen (O₂), and the reactive species are excited oxygen atoms (O*), and the excited carbon atoms (C*) and the excited hydrogen atoms (H*) react with the excited oxygen atoms (O*) to generate carbon dioxide (CO₂) gas, carbon monoxide (CO) gas, and water vapor (H₂O).

27. The exhaust gas pretreatment equipment of claim 1, further comprising an exhaust pipe plasma gas supplier supplying an exhaust gas plasma source gas to the exhaust pipe plasma reactor, wherein the exhaust pipe plasma reactor decomposes the exhaust pipe plasma source gas to generate reactive species.

28. Exhaust gas pretreatment equipment for semiconductor manufacturing facilities, the exhaust gas pretreatment equipment for pretreating an exhaust gas discharged from a semiconductor process chamber in which a semiconductor manufacturing process using a process gas is performed, by using a vacuum pump through a chamber exhaust pipe connecting the semiconductor process chamber to the vacuum pump, the exhaust gas pretreatment equipment comprising:
an exhaust pipe plasma reactor installed on the chamber exhaust pipe and generating plasma in the exhaust gas to remove ingredients to be removed contained in the exhaust gas; and
a remote plasma reactor generating plasma to decompose a remote plasma source gas and generating a remote plasma gas including reactive species,
wherein the remote plasma gas is supplied to a section between the semiconductor process chamber and the exhaust pipe plasma reactor in a flow line of the exhaust gas.

29. The exhaust gas pretreatment equipment of claim 28, wherein the reactive species react with powder ingredients in the exhaust pipe plasma reactor and gasifies the powder ingredients.

30. (canceled)
